(19) United States
(12) Patent Application Publication
(10) Pub. No.: US 2024/0204002 A1
(43) Pub. Date: Jun. 20, 2024

(54) ARRAY SUBSTRATE AND METHOD FOR MANUFACTURING SAME, DISPLAY PANEL, AND DISPLAY DEVICE

(71) Applicant: BOE Technology Group Co., Ltd., Beijing (CN)

(72) Inventors: Zhen ZHANG, Beijing (CN); Fuqiang LI, Beijing (CN); Zhenyu ZHANG, Beijing (CN); Lizhong WANG, Beijing (CN); Yunping DI, Beijing (CN); Ce NING, Beijing (CN); Zheng FANG, Beijing (CN); Chenyang ZHANG, Beijing (CN); Yawei WANG, Beijing (CN); Wei WANG, Beijing (CN); Hongrun WANG, Beijing (CN); Binbin TONG, Beijing (CN); Nianqi YAO, Beijing (CN); Jiahui HAN, Beijing (CN); Chengfu XU, Beijing (CN); Pengxia LIANG, Beijing (CN)

(21) Appl. No.: 17/910,525

(22) PCT Filed: Oct. 28, 2021
(86) PCT No.: PCT/CN2021/127111

§ 371 Date: Sep. 9, 2022

(30) Foreign Application Priority Data
Apr. 19, 2021 (CN) 202110417335.3

(51) Int. Cl. H01L 27/12; G02F 1/1362; G02F 1/1368

(52) U.S. Cl. CPC H01L 27/1225; G02F 1/136222; G02F 1/136227; G02F 1/136295; G02F 1/1368; H01L 27/124; H01L 27/127

(57) ABSTRACT

Embodiments of the present disclosure provide an array substrate and method for manufacturing same, a display panel, and a display device, and relate to the field of display technologies. The array substrate includes a color filter layer, such that a distance between a light source on a side, distal from the color filter layer, of the base substrate and the color filter layer is less. Thus, light from regions of the color resist blocks is avoided being emitted from adjacent color resist blocks, and a cross color of the display panel is further avoided, such that the display effect of the display panel is great. In addition, the color resist block is at least partially overlapped with a second portion of a metal oxide pattern in an oxide thin film transistor, such that an overall footprint of the oxide thin film transistor and the color filter layer can be reduced, so as to acquire the display panel of high PPI.

### CROSS-REFERENCE TO RELATED APPLICATION

This application is a U.S. national stage of international application No. PCT/CN2021/127111, filed on Oct. 28, 2021, which is based on and claims the priority to Chinese Patent Application No. 202110417335.3, filed on Apr. 19, 2021 and entitled “ARRAY SUBSTRATE AND PREPARATION METHOD THEREOF, DISPLAY PANEL AND DISPLAY DEVICE,” the disclosures of which are incorporated herein by reference in their entireties.

### TECHNICAL FIELD

The present disclosure relates to the field of display technologies, and in particular, relates to an array substrate and method for manufacturing same, a display panel, and a display device.

### BACKGROUND

With the developments of the field of display technologies, market requirements for a higher pixels per inch (PPI) of a display panel is becoming higher.

### SUMMARY

Embodiments of the present disclosure provide an array substrate and method for manufacturing same, a display panel, and a display device. The technical solutions are as follows.

According to some embodiments of the present disclosure, an array substrate is provided. The array substrate includes:
a base substrate, wherein the base substrate includes a display region;
a plurality of oxide thin film transistors spaced apart from each other in the display region, wherein each of the plurality of oxide thin film transistors includes a metal oxide pattern including a first portion, a channel portion, and a second portion that are sequentially connected, wherein the first portion is configured to receive a data signal; and
a color filter layer disposed in the display region, wherein the color filter layer is disposed between the metal oxide pattern and the base substrate, and the color filter layer includes a plurality of color resist blocks of different colors in one-to-one correspondence to the plurality of oxide thin film transistors, wherein an orthogonal projection of each of the plurality of color resist blocks on the base substrate is at least partially overlapped with an orthogonal projection of the second portion of the corresponding oxide thin film transistor on the base substrate.

In some embodiments, both a conductivity of the first portion and a conductivity of the second portion are greater than a conductivity of the channel portion.

In some embodiments, the array substrate further includes: a plurality of data lines and a first insulation layer;
wherein the plurality of data lines are disposed between the metal oxide pattern and the base substrate, the first insulation layer is disposed between the plurality of data lines and the metal oxide pattern, and the first insulation layer is provided with a plurality of first via holes;
wherein each of the plurality of data lines is electrically connected to the first portion of at least one of the plurality of oxide thin film transistors via at least one of the plurality of first via holes.

In some embodiments, the first insulation layer is a first passivation layer disposed between the plurality of data lines and the color filter layer;
wherein a distance between a face, proximal to the base substrate, of a target portion of the second portion and the base substrate is greater than a distance between a face, proximal to the base substrate, of the first portion and the base substrate, and greater than a distance between a face, proximal to the base substrate, of the channel portion and the base substrate, wherein the target portion is a section of the second portion with the orthogonal projection on the base substrate overlapped with the orthogonal projection of the color resist block on the base substrate.

In some embodiments, the first insulation layer includes: a first passivation layer disposed between the plurality of data lines and the color filter layer, a planarization layer disposed between the color filter layer and the metal oxide pattern, and a second passivation layer disposed between the planarization layer and the metal oxide pattern.

In some embodiments, the array substrate further includes: a second insulation layer disposed on a side, distal from the base substrate, of the second portion, and a common electrode disposed on a side, distal from the base substrate, of the second insulation layer;
wherein an orthogonal projection of the common electrode on the base substrate is at least partially overlapped with the orthogonal projection of the second portion on the base substrate, and the second portion is taken as a pixel electrode to drive, with the common electrode, liquid crystals to be deflected.

In some embodiments, the array substrate further includes: a third insulation layer, a pixel electrode, a fourth insulation layer, and a common electrode that are disposed on a side, distal from the base substrate, of the metal oxide pattern and are sequentially laminated in a direction away from the base substrate; wherein an orthogonal projection of the pixel electrode on the base substrate is at least partially overlapped with an orthogonal projection of the common electrode on the base substrate;
the third insulation layer is provided with a plurality of second via holes, wherein each of the plurality of second via holes is configured to expose at least part of the second portion of one oxide thin film transistor; and the pixel electrode is electrically connected to the second portion via the plurality of second via holes.

In some embodiments, each of the plurality of oxide thin film transistors further includes: a first gate electrode pattern disposed in the display region, and the array substrate further includes: a fifth insulation layer; wherein the first gate electrode pattern is disposed between the metal oxide pattern and the base substrate, the fifth insulation layer is disposed between the first gate electrode pattern and the metal oxide pattern,
and in each of the plurality of oxide thin film transistors, an orthogonal projection of the first gate electrode pattern on the base substrate covers an orthogonal projection of the channel portion in the metal oxide pattern on the base substrate.

In some embodiments, the array substrate further includes: a plurality of scan lines extending in a pixel row direction;
wherein the plurality of scan lines are disposed on a side, proximal to the base substrate, of the first gate electrode pattern, each of the plurality of scan lines is at least partially in contact with the first gate electrode pattern of at least one oxide thin film transistor, and a length, in a pixel column direction, of the orthogonal projection of the first gate electrode pattern on the base substrate is greater than a length, in the pixel column direction, of an orthogonal projection of the scan line on the base substrate.

In some embodiments, the base substrate further includes a peripheral region on a side of the display region, and the array substrate further includes: a drive circuit disposed in the peripheral region; wherein the drive circuit includes at least one poly-silicon thin film transistor, wherein each poly-silicon thin film transistor includes: a second gate electrode pattern, and a source-drain electrode pattern;
wherein the second gate electrode pattern and the plurality of scan lines are disposed on a same layer, and the source-drain electrode pattern and a plurality of data lines of the array substrate are disposed on a same layer.

In some embodiments, each poly-silicon thin film transistor further includes: an active pattern; and the array substrate further includes: a sixth insulation layer; wherein the active pattern is disposed between the second gate electrode pattern and the base substrate, the sixth insulation layer is disposed between the active pattern and the second gate electrode pattern,
and the source-drain electrode pattern is electrically connected to the active pattern.

According to some embodiments of the present disclosure, a method for manufacturing an array substrate is provided. The method includes:
providing a base substrate, wherein the base substrate includes a display region; and
forming a plurality of oxide thin film transistors spaced apart from each other and a color filter layer in the display region;
wherein each of the plurality of oxide thin film transistors includes a metal oxide pattern including a first portion, a channel portion, and a second portion that are sequentially connected, wherein the first portion is configured to receive a data signal; and the color filter layer is disposed between the metal oxide pattern and the base substrate, and the color filter layer includes a plurality of color resist blocks of different colors in one-to-one correspondence to the plurality of oxide thin film transistors, wherein an orthogonal projection of each of the plurality of color resist blocks on the base substrate is at least partially overlapped with an orthogonal projection of the second portion of the corresponding oxide thin film transistor on the base substrate.

In some embodiments, forming the metal oxide pattern of the oxide thin film transistor includes:
forming a metal oxide thin film on a side of the base substrate;
acquiring a metal oxide structure by patterning the metal oxide thin film;
coating a photoresist on a first region on a side, distal from the base substrate, of the metal oxide structure, wherein the side, distal from the base substrate, of the metal oxide structure further includes a second region and a third region, wherein the second region and the third region are disposed on two sides of the first region;
acquiring the first portion and the second portion of the metal oxide pattern by conducting a conductor transformation treatment on the second region and the third region on the side, distal from the base substrate, of the metal oxide structure; and
acquiring the channel portion of the metal oxide pattern by removing the photoresist.

According to some embodiments of the present disclosure, a display panel is provided. The display panel includes: a cover plate, a liquid crystal layer, and the array substrate according to above embodiments;
wherein the liquid crystal layer is disposed between the cover plate and the array substrate.

According to some embodiments of the present disclosure, a display device is provided. The display device includes: a power supply assembly and the display panel according to above embodiments;
wherein the power supply assembly is configured to supply power to the display panel.

### BRIEF DESCRIPTION OF THE DRAWINGS

For clearer description of the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without any creative efforts.

FIG. 1 is a schematic structural diagram of an array substrate according to some embodiments of the present disclosure;

FIG. 2 is a top view of a base substrate according to some embodiments of the present disclosure;

FIG. 3 is a schematic diagram of locations of a color filter layer and a light source according to some embodiments of the present disclosure;

FIG. 4 is a schematic diagram of locations of a color filter layer and a light source in other way;

FIG. 5 is a schematic structural diagram of another array substrate according to some embodiments of the present disclosure;

FIG. 6 is a schematic structural diagram of another array substrate according to some embodiments of the present disclosure;

FIG. 7 is a schematic structural diagram of another array substrate according to some embodiments of the present disclosure;

FIG. 8 is a flowchart of a method for manufacturing an array substrate according to some embodiments of the present disclosure;

FIG. 9 is a flowchart of another method for manufacturing an array substrate according to some embodiments of the present disclosure;

FIG. 10 is a cross-sectional diagram of forming a second gate electrode pattern and a scan line according to some embodiments of the present disclosure;

FIG. 11 is a top view of scan lines according to some embodiments of the present disclosure;

FIG. 12 is a top view of forming a first gate electrode pattern according to some embodiments of the present disclosure;

FIG. 13 is a cross-sectional diagram of forming a source-drain electrode pattern and a data line according to some embodiments of the present disclosure;

FIG. 14 is a top view of forming a data line according to some embodiments of the present disclosure;

FIG. 15 is a top view of forming a color resist block according to some embodiments of the present disclosure;

FIG. 16 is a cross-sectional diagram of forming a first via hole according to some embodiments of the present disclosure;

FIG. 17 is a top view of forming a first via hole according to some embodiments of the present disclosure;

FIG. 18 is a top view of forming a metal oxide structure according to some embodiments of the present disclosure;

FIG. 19 is a top view of coating a photoresist on a first region according to some embodiments of the present disclosure;

FIG. 20 is a cross-sectional diagram of coating a photoresist on a first region according to some embodiments of the present disclosure;

FIG. 21 is a cross-sectional diagram of conducting a conductor transformation treatment on a second region and a third region according to some embodiments of the present disclosure;

FIG. 22 is a schematic diagram of a high resistance region according to some embodiments of the present disclosure;

FIG. 23 is a top view of forming a metal oxide pattern according to some embodiments of the present disclosure;

FIG. 24 is a top view of forming a common electrode according to some embodiments of the present disclosure;

FIG. 25 is a flowchart of another method for manufacturing an array substrate according to some embodiments of the present disclosure;

FIG. 26 is a top view of forming a metal oxide structure according to some embodiments of the present disclosure;

FIG. 27 is a top view of coating a photoresist on a first region according to some embodiments of the present disclosure;

FIG. 28 is a top view of forming a metal oxide pattern according to some embodiments of the present disclosure;

FIG. 29 is a cross-sectional diagram of forming a second via hole according to some embodiments of the present disclosure;

FIG. 30 is a top view of forming a second via hole according to some embodiments of the present disclosure;

FIG. 31 is a top view of forming a pixel electrode according to some embodiments of the present disclosure;

FIG. 32 is a top view of forming a common electrode according to some embodiments of the present disclosure;

FIG. 33 is a flowchart of another method for manufacturing an array substrate according to some embodiments of the present disclosure;

FIG. 34 is a cross-sectional diagram of forming a first via hole according to some embodiments of the present disclosure;

FIG. 35 is a schematic structural diagram of a display panel according to some embodiments of the present disclosure; and

FIG. 36 is a schematic structural diagram of a display device according to some embodiments of the present disclosure.

### DETAILED DESCRIPTION

To make the objectives, technical solutions, and advantages of the present disclosure clearer, the embodiments of the present disclosure are further described in detail hereinafter with reference to the accompanying drawings.

In the related art, a display panel includes a drive circuit, and a plurality of sub-pixels of different colors. Each of the plurality of sub-pixels can emit light under driving of the drive circuit, such that a color display of the display panel is achieved.

However, as sizes of sub-pixels in a display panel of high PPI are less, and distances between adjacent sub-pixels are less, light emitted by the sub-pixels is prone to cross color, such that the display effect of the display panel is affected.

Recently, with the pluralistic expansion of the application field of virtual reality (VR), requirements for VR products are increasing. As the display panel in the VR product is a core hardware thereof, the display panel needs to include a greater number of pixels to restore a real scene. That is, the requirements for the display panel of high PPI in the VR product are becoming higher.

However, in the display panel of the existing VR product, a thin film transistor (TFT) in the sub-pixel in the display region of the array substrate is generally a poly-silicon TFT. A magnitude of a leakage current of the poly-silicon TFT is greater (10⁻¹¹), that is, the leakage current is greater, such that a voltage of the sub-pixel is unstable when the sub-pixel displays. Thus, the display panel of high PPI (such as a display panel of PPI greater than 1000 PPI) cannot display normally. In addition, as the sizes of sub-pixels in the display panel of high PPI are less, and the distances between adjacent sub-pixels are less, light emitted by the sub-pixels is prone to cross color, such that the display effect of the display panel is poor.

The terms in the embodiments of the present disclosure are merely used to explain the embodiments of the present disclosure, and are not intended to limit the present disclosure. Unless otherwise defined, technical or scientific terms used in the embodiments of the present disclosure shall have ordinary meaning understood by persons of ordinary skill in the art to which the disclosure belongs. The terms “first,” “second,” “third,” and the like used in the specification and claims of the present disclosure are not intended to indicate any order, quantity or importance, but are merely used to distinguish the different components. The terms “one” and “a” are not intended to indicate limitation of the number, but are used to indicate the presence of at least one. The terms “comprise,” “include,” and the like are used to indicate that the element or object preceding the terms “comprise,” “include,” or the like covers the element or object following the terms “comprise,” “include,” or the like and its equivalents, and shall not be understood as excluding other elements or objects. The terms “connect,” “contact,” and the like are not intended to be limited to physical or mechanical connections, but may include electrical connections, either direct or indirect connection. The terms “on,” “under,” “left,” and “right” are only used to indicate the relative positional relationship. In the case that the absolute position of the described object changes, the relative positional relationship may change accordingly.

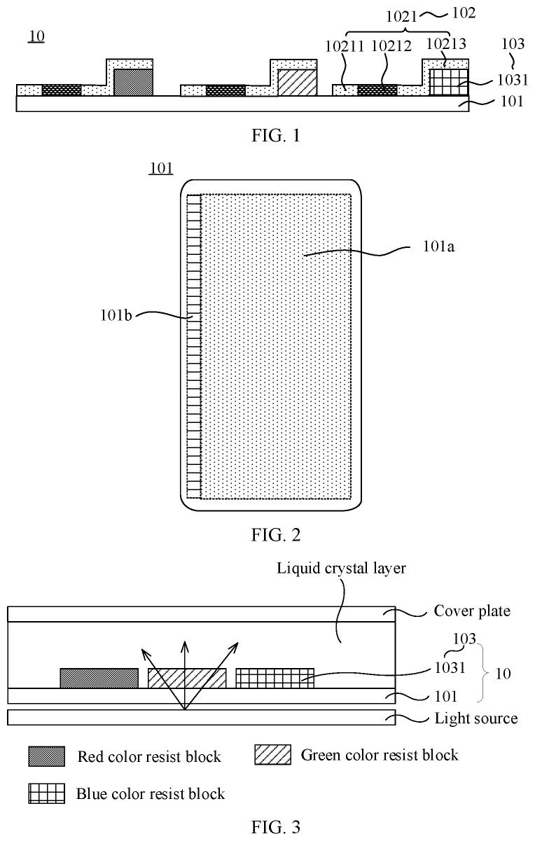

FIG. 1 is a schematic structural diagram of an array substrate according to some embodiments of the present disclosure. Referring to FIG. 1, the array substrate 10 includes: a base substrate 101, a plurality of oxide thin film transistors 102 spaced apart from each other, and a color filter layer 103.

FIG. 2 is a top view of a base substrate according to some embodiments of the present disclosure. Referring to FIG. 2, the base substrate 101 includes a display region 101a. The plurality of oxide thin film transistors 102 and the color filter layer 103 in the array substrate 10 are disposed in the display region 101a of the base substrate 101. The display region 101a is also referred to as an active display area (AA).

As a magnitude of a leakage current of the oxide thin film transistor 102 is less (10⁻¹³) that is, the leakage current is less, such that the stability of the voltage of the display region 101a in displaying an image is improved. Thus, the display panel can display normally.

Referring to FIG. 1, each of the plurality of oxide thin film transistors 102 includes a metal oxide pattern 1021. The metal oxide pattern 1021 includes a first portion 10211, a channel portion 10212, and a second portion 10213 that are sequentially connected. The first portion 10211 is configured to receive a data signal.

Referring to FIG. 1, the color filter layer 103 is disposed between the metal oxide pattern 1021 and the base substrate 101. That is, the metal oxide pattern 1021 is disposed on a side, distal from the base substrate 101, of the color filter layer 103. The color filter layer 103 includes a plurality of color resist blocks 1031 of different colors in one-to-one correspondence to the plurality of oxide thin film transistors 102. For example, FIG. 1 shows three oxide thin film transistors 102 and three color resist blocks 1031, and different filling patterns indicate different colors of the color resist blocks 1031.

An orthogonal projection of each of the plurality of color resist blocks 1031 on the base substrate 101 is at least partially overlapped with an orthogonal projection of the second portion 10213 of the corresponding oxide thin film transistor 102 on the base substrate 101. In addition, as the color resist block 1031 is at least partially overlapped with the second portion 10213 of the metal oxide pattern 1021, the overall footprint of the metal oxide pattern 1021 and the color resist block 1031 on the base substrate 101 can be reduced, so as to acquire the display panel of high PPI.

In some embodiments, colors of any two adjacent color resist blocks 1031 of the plurality of color resist blocks 1031 in the color filter layer 103 are different. In the embodiments of the present disclosure, referring to FIG. 3, as the color filter layer 103 is disposed on a side of the array substrate 10, that is, the array substrate 10 is a color film on array (COA) substrate, a distance between a light source on a side, distal from the color filter layer 103, of the base substrate 101 and the color filter layer 103 is less. Thus, light from the region of the color resist blocks 1031 in the color filter layer 103 is avoided being emitted from adjacent color resist blocks 1031, and the cross color of the display panel is further avoided, such that the display effect of the display panel is ensured.

In summary, an array substrate is provided in the embodiments of the present disclosure. The array substrate includes a color filter layer, such that a distance between a light source on a side, distal from the color filter layer, of the base substrate and the color filter layer is less. Thus, light from the region of the color resist blocks is avoided being emitted from adjacent color resist blocks, and the cross color of the display panel is further avoided, such that the display effect of the display panel is great. In addition, the color resist block is at least partially overlapped with a second portion of the metal oxide pattern in the oxide thin film transistor, such that the overall footprint of the oxide thin film transistor and the color filter layer can be reduced, so as to acquire the display panel of high PPI.

In some embodiments, a material of the metal oxide pattern 1021 includes indium gallium zinc oxide (IGZO). Both a conductivity of the first portion 10211 and a conductivity of the second portion 10213 are greater than a conductivity of the channel portion 10212. For example, a conducting process is performed on the first portion 10211 and the second portion 10213, and a conducting process is not performed on the channel portion 10212.

In some embodiments, referring to FIG. 3, the color filter layer 103 includes a plurality of red color resist blocks 1031, a plurality of green color resist blocks 1031, and a plurality of blue color resist blocks 1031. The plurality of red color resist blocks 1031 are used to transmit red light, the plurality of green color resist blocks 1031 are used to transmit green light, and plurality of blue color resist blocks 1031 are used to transmit blue light. Thicknesses of the plurality of color resist blocks 1031 in the color filter layer 103 range from 1 μm to 2 μm.

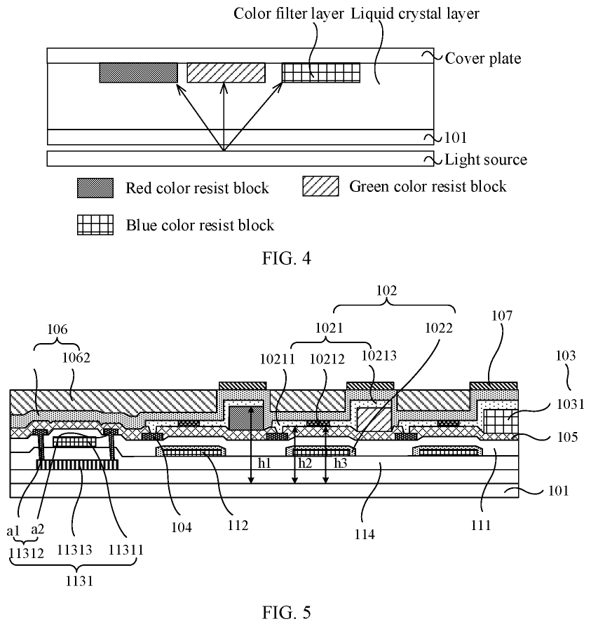

In the display panel of high PPI, referring to FIG. 4, in the case that only green color resist blocks are displayed, light from a region of the green color resist blocks 1031 emits through adjacent red color resist blocks or blue color resist blocks, thereby causing a cross color. For solving the problem, referring to FIG. 3, in the embodiments of the present disclosure, the color filter layer 103 is disposed on a side of the array substrate 10, such that a distance between the color filter layer 103 and the light source is greatly reduced. Thus, in the case that only green color resist blocks are displayed, light from a region of the green color resist blocks 1031 does not emit through adjacent red color resist blocks or blue color resist blocks, and thus the cross color is reduced.

FIG. 5 is a schematic structural diagram of another array substrate according to some embodiments of the present disclosure. Referring to FIG. 5, the array substrate 10 further includes: a plurality of data lines 104 and a first insulation layer 105. The plurality of data lines 104 are disposed between the metal oxide pattern 1021 and the base substrate 101, the first insulation layer 105 is disposed between the plurality of data lines 104 and the metal oxide pattern 1021, and the first insulation layer 105 is configured to insulate the metal oxide pattern 1021 and the plurality of data lines 104.

The first insulation layer 105 is provided with a plurality of first via holes, and each of the plurality of first via holes is configured to expose at least part of one data line 104. An orthogonal projection of the first portion 10211 of each metal oxide pattern 1021 on the base substrate 101 is at least partially overlapped with an orthogonal projection of one first via hole on the base substrate 101. For example, at least part of the first portion 10211 of each metal oxide pattern 1021 is disposed within one first via hole, and is electrically connected to one data line 104 exposed from the first via hole.

In some embodiments, each data line 104 is electrically connected to the first portion 10211 of at least one oxide thin film transistor 102 via at least one first via hole, such that the data line 104 supplies a data signal to the first portion 10211 of at least one oxide thin film transistor 102.

In some embodiments, the plurality of data lines 104 extend in a pixel column direction, the first insulation layer 105 includes a plurality of target first via hole arranged in the pixel column direction, the array substrate 10 includes a plurality of first target oxide thin film transistors arranged in the pixel column direction, and the plurality of first target oxide thin film transistors arranged in the pixel column direction are in one-to-one correspondence to the plurality of target first via hole arranged in the pixel column direction. Each data line 104 is electrically connected to the first portion 10211 of the first target oxide thin film transistor in the same column via a corresponding target first via hole.

In some embodiments, referring to FIG. 5, the first insulation layer 105 is a first passivation (PVX) layer disposed between the plurality of data lines 104 and the color filter layer 103. As a thickness of the color resist block 1031 in the color filter layer 103 is great, and the first insulation layer 105 does not include a planarization layer (PLN) disposed on a side, distal from the base substrate 101, of the color filter layer 103, a distance between a section of the metal oxide pattern 1021 overlapped with the color resist block 1031 and the base substrate 101 is greater, and a distance between a section of the metal oxide pattern 1021 not overlapped with the color resist block 1031 in the color filter layer 103 and the base substrate 101 is less. The section of the metal oxide pattern 1021 overlapped with the color resist block 1031 is a section of the metal oxide pattern 1021 with an orthogonal projection on the base substrate 101 overlapped with the orthogonal projection of the color resist block 1031 on the base substrate 101. The section of the metal oxide pattern 1021 not overlapped with the color resist block 1031 is a section of the metal oxide pattern 1021 with an orthogonal projection on the base substrate 101 not overlapped with the orthogonal projection of the color resist block 1031 on the base substrate 101.

In some embodiments, a distance h1 between a face, proximal to the base substrate 101, of a target portion of the second portion 10213 of the metal oxide pattern 1021 and the base substrate 101 is greater than a distance h2 between a face, proximal to the base substrate 101, of the first portion 10211 and the base substrate 101, and greater than a distance h3 between a face, proximal to the base substrate 101, of the channel portion 10212 and the base substrate 101. The target portion is a section of the second portion 10213 with the orthogonal projection on the base substrate 101 overlapped with the orthogonal projection of the color resist block 1031 on the base substrate 101.

Referring to FIG. 5, the face, proximal to the base substrate 101, of a target portion of the second portion 10213 of the metal oxide pattern 1021 is not coplanar with both the face, proximal to the base substrate 101, of the first portion 10211 and the face, proximal to the base substrate 101, of the channel portion 10212. In addition, the face, proximal to the base substrate 101, of the first portion 10211 is coplanar with the face, proximal to the base substrate 101, of the channel portion 10212. That is, the distance h2 between the face, proximal to the base substrate 101, of the first portion 10211 and the base substrate 101 is equal to the distance h3 between the face, proximal to the base substrate 101, of the channel portion 10212 and the base substrate 101, that is, h2 is equal to h3.

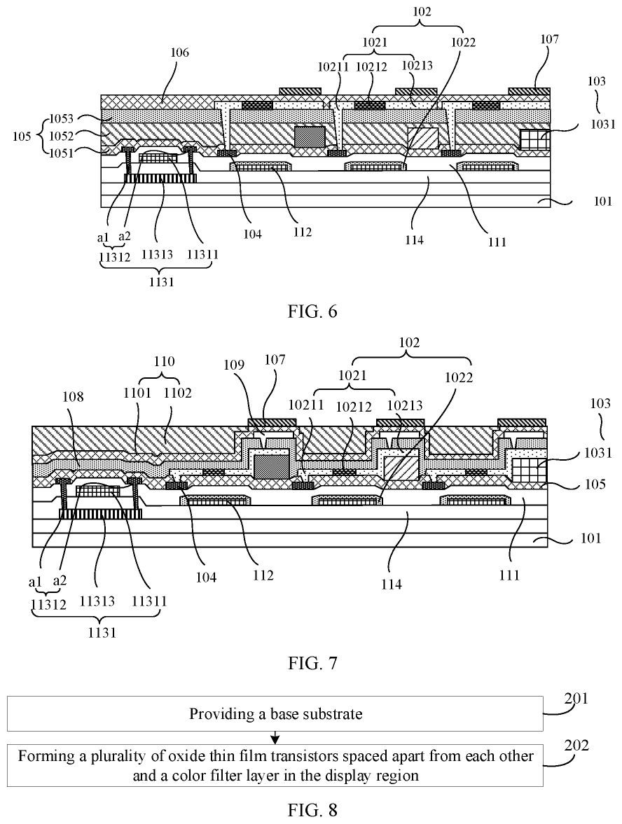

In some embodiments, referring to FIG. 6, the first insulation layer 105 includes: a first passivation layer 1051 disposed between the plurality of data lines 104 and the color filter layer 103, a planarization layer 1052 disposed between the color filter layer 103 and the metal oxide pattern 1021, and a second passivation layer 1053 disposed between the planarization layer 1052 and the metal oxide pattern 1021. That is, the first passivation layer 1051, the planarization layer 1052, and the second passivation layer 1053 are sequentially laminated in a direction away from the base substrate 101.

Although the thickness of the color resist block 1031 in the color filter layer 103 is great, the first insulation layer 105 includes the planarization layer 1052 disposed between the metal oxide pattern 1021 and the color filter layer 103, such that a face, proximal to the base substrate 101, of a film layer on a face, distal from the base substrate 101, of the planarization layer 1052 is a plane. The face, distal from the base substrate 101, of the planarization layer 1052 is a plane, and is substantially parallel to a bearing face of the base substrate 101. That is, a periphery of the color resist block 1031 in the array substrate 10 is filled by disposing the planarization layer 1052, that is, a region including the color resist block 1031 and a region not including the color resist block 1031 are planarized.

In some embodiments, as a face, distal from the base substrate 101, of the planarization layer 1052 in the first insulation layer 105 is the second passivation layer 1053, a face, proximal to the base substrate 101, of the second passivation layer 1053 is a plane. In addition, as the second passivation layer 1053 is a complete cover, the planarization of the array substrate 10 is not affected. That is, a face, proximal to the base substrate 101, of the metal oxide pattern 1021 on a face, distal from the base substrate 101, of the second passivation layer 1053 is also a plane. That is, the distance between the face, proximal to the base substrate 101, of the second portion 10213 of the metal oxide pattern 1021 and the base substrate 101, the distance between the face, proximal to the base substrate 101, of the first portion 10211 of the metal oxide pattern 1021 and the base substrate 101, and the distance between the face, proximal to the base substrate 101, of the channel portion 10212 of the metal oxide pattern 1021 and the base substrate 101 are equal.

In some embodiments, the face, proximal to the base substrate 101, of the second portion 10213 of the metal oxide pattern 1021, the face, proximal to the base substrate 101, of the first portion 10211 of the metal oxide pattern 1021, and the face, proximal to the base substrate 101, of the channel portion 10212 of the metal oxide pattern 1021 are coplanar.

In the embodiments of the present disclosure, as the pixel electrode (for example, the second portion 10213 of the metal oxide pattern 1021 in FIG. 5 and FIG. 6, the pixel electrode 107 in FIG. 7) in the array substrate is disposed on the side, distal from the base substrate, of the color filter layer 103, and the data line 104 is disposed on the side, proximal to the base substrate, of the color filter layer 103, a distance, in a direction perpendicular to the bearing face of the base substrate 101, between the pixel electrode and the data line 104 in the array substrate is great, such that the effect of the coupling capacitance generated by the second portion 10213 and the data line 104 on the display effect is avoided.

In the embodiments of the present disclosure, referring to FIG. 5 and FIG. 6, the array substrate 10 further includes: a second insulation layer 106 disposed on a side, distal from the base substrate 101, of the second portion 10213, and a common electrode 107 disposed on a side, distal from the base substrate 101, of the second insulation layer 106. An orthogonal projection of the common electrode 107 on the base substrate 101 is at least partially overlapped with the orthogonal projection of the second portion 10213 on the base substrate 101, and the second portion 10213 is taken as the pixel electrode to form, with the common electrode, an electric field to drive liquid crystals to be deflected.

That is, in the technical solution of the embodiments of the present disclosure, the pixel electrode is not prepared separately, such that the structure of the array substrate 10 is simplified, and the cost for manufacturing the array substrate 10 is reduced.

In the array substrate 10 shown in FIG. 5, the first insulation layer 105 in the array substrate 10 does not include the planarization layer. Thus, for ensuring the planarization of the array substrate 10, the second insulation layer 106 includes: a second passivation layer 1061 disposed on a side, distal from the base substrate 101, of the metal oxide pattern 1021, and a planarization layer 1062 disposed on a side, distal from the base substrate 101, of the second passivation layer 1061.

A face, distal from the base substrate 101, of the planarization layer 1062 is a plane, and is substantially parallel to the bearing face of the base substrate 101. That is, a periphery of the color resist block 1031 in the array substrate 10 is filled by disposing the planarization layer 1062, that is, a region including the color resist block 1031 and a region not including the color resist block 1031 are planarized.

In the array substrate 10 shown in FIG. 6, the first insulation layer 105 in the array substrate 10 includes the planarization layer. Thus, the planarization of the array substrate 10 is great, and the second insulation layer 106 is a third passivation layer disposed on a side, distal from the base substrate 101, of the metal oxide pattern 1021.

In the array substrate 10 shown in FIG. 6, the face, distal from the base substrate 101, of the planarization layer 1062 further includes the metal oxide pattern 1021, and the metal oxide pattern 1021 is not the complete cover. Thus, the metal oxide pattern 1021 affects the planarization of the array substrate 10. As such, the second insulation layer 106 in the array substrate 10 shown in FIG. 6 includes the third passivation layer disposed on the side, distal from the base substrate 101, of the metal oxide pattern 1021, and another planarization layer disposed in a side, distal from the base substrate 101, of the third passivation layer. The common electrode 107 is disposed on a side, distal from the base substrate 101, of another planarization layer. That is, the array substrate 10 in the technical solutions includes two planarization layers.

In the embodiments of the present disclosure, referring to FIG. 7, the array substrate 10 further includes: a third insulation layer 108, a pixel electrode 109, a fourth insulation layer 110, and the common electrode 107 that are disposed on a side, distal from the base substrate 101, of the metal oxide pattern 1021 and are sequentially laminated in the direction away from the base substrate 101. An orthogonal projection of the pixel electrode 109 on the base substrate 101 is at least partially overlapped with an orthogonal projection of the common electrode 107 on the base substrate 101. The pixel electrode 109 and the common electrode 107 form an electric field to drive liquid crystals to be deflected.

The third insulation layer 108 is provided with a plurality of second via holes. Each of the plurality of second via holes is configured to expose at least part of the second portion 10213 of one oxide thin film transistor 102. The pixel electrode 109 is electrically connected to the second portion 10213 via the plurality of second via holes, such that the second portion 10213 provides the drive signal to the pixel electrode 109.

In some embodiments, each of the plurality of oxide thin film transistors 102 in the embodiments of the present disclosure corresponds to one pixel electrode 109. For example, the pixel electrode 109 is electrically connected to the second portion 10213 of corresponding oxide thin film transistor 102 via the second via hole.

In the array substrate 10 shown in FIG. 7, the first insulation layer 105 in the array substrate 10 includes the first passivation layer, and does not include the planarization layer. Thus, for ensuring the planarization of the array substrate 10, the fourth insulation layer 110 includes: a second passivation layer 1101 disposed on a side, distal from the base substrate 101, of the pixel electrode 109, and a planarization layer 1102 disposed on a side, distal from the base substrate 101, of the second passivation layer 1101.

A face, distal from the base substrate 101, of the planarization layer 1102 is a plane, and is substantially parallel to the bearing face of the base substrate 101. That is, by disposing the planarization layer 1102, a region including the color resist block 1031 and a region not including the color resist block 1031 are planarized.

In the embodiments of the present disclosure, referring to FIG. 5 to FIG. 7, each oxide thin film transistor 102 further includes a first gate electrode pattern 1022 disposed in the display region 101a. The array substrate 10 further includes a fifth insulation layer 111. The first gate electrode pattern 1022 is disposed between the metal oxide pattern 1021 and the base substrate 101, and the fifth insulation layer 111 is disposed between the first gate electrode pattern 1022 and the metal oxide pattern 1021.

In each oxide thin film transistor 102, an orthogonal of the first gate electrode pattern 1022 on the base substrate 101 covers an orthogonal projection of the channel portion 10212 of the metal oxide pattern 1021 on the base substrate 101. That is, the orthogonal projection of the channel portion 10212 on the base substrate 101 falls within the orthogonal of the first gate electrode pattern 1022 on the base substrate 101.

In some embodiments, a material of the first gate electrode pattern 1022 is indium tin oxide (ITO).

In some embodiments, referring to FIG. 5 to FIG. 7, the array substrate 10 further includes: a plurality of scan lines 112. The plurality of scan lines 112 extend in a pixel row direction. The plurality of scan lines 112 are disposed on a side, proximal to the base substrate 101, of the first gate electrode pattern 1022, and each of the plurality of scan lines 112 is at least partially in contact with the first gate electrode pattern 1022 of at least one oxide thin film transistor 102. Each of the plurality of scan lines 112 is configured to provide a scan signal the belonging oxide thin film transistor 102 of the contacted first gate electrode pattern 1022. The pixel column direction is perpendicular to the pixel row direction.

In some embodiments, the array substrate 10 includes: a plurality of second target oxide thin film transistors arranged in the pixel row direction, and each of the plurality of scan lines 112 is in contact with the first gate electrode pattern 1022 of the plurality of second target oxide thin film transistors on the same row.

A length, in the pixel column direction, of the orthogonal projection of the first gate electrode pattern 1022 on the base substrate 101 is greater than a length, in the pixel column direction, of an orthogonal projection of the scan line 112 on the base substrate 101, such that the orthogonal projection of the first gate electrode pattern 1022 on the base substrate 101 covers the orthogonal projection of the channel portion 10212 of the metal oxide pattern 1021 on the base substrate 101.

A material of the scan line 112 is a non-transparent material. The scan line can provide the scan signal to the first gate electrode pattern 1022 of the oxide thin film transistor 102, and can function as a shielding layer of the oxide thin film transistor to ensure normal property of the oxide thin film transistor 102 under backlight.

Referring to FIG. 2, the base substrate 101 further includes a peripheral region 101b on a side of the display region 101a. The peripheral region 101b in FIG. 2 is disposed on the left side of the display region 101a, and the peripheral region 101b is also disposed on the right side of the display region 101a, which is not limited in the embodiments of the present disclosure.

In some embodiments, the display region 101a is provided with a plurality of sub-pixels, and each of the plurality of sub-pixels includes: a light-emitting unit and a pixel circuit. The oxide thin film transistor 102, disposed in the display region 101a, of the array substrate 10 is taken as the transistor in the pixel circuit of the sub-pixel. In addition, the array substrate 10 further includes: a drive circuit 113. The drive circuit is disposed in the peripheral region 101b, and is connected to the plurality of sub-pixels to provide the drive signal to the plurality of sub-pixels. For example, the drive circuit is connected to the oxide thin film transistor 102 in the pixel circuit of the sub-pixel, and the drive circuit is a gate driver on array (GOA).

In some embodiments, the drive circuit 113 in the peripheral region 101b is connected to the plurality of data lines 112, and the plurality of data lines 112 is connected to the oxide thin film transistor 102 in the display region 101a. As such, the drive circuit 113 provides the scan signal to the oxide thin film transistor 102 through the plurality of data lines 112.

In the embodiments of the present disclosure, referring to FIG. 5 to FIG. 7, the drive circuit 113 includes at least one poly-silicon thin film transistor 1131, and FIG. 5 to FIG. 7 show one poly-silicon thin film transistor 1131.

As the driving capability of the poly-silicon thin film transistor 1131 is great, the transistor in the drive circuit 113 is designed as the poly-silicon thin film transistor 1131, so as to ensure the driving capability of the drive circuit 113 in the display region 101a.

In some embodiments, the drive circuit 113 in the peripheral region 101b includes at least one poly-silicon thin film transistor, and the oxide thin film transistor 102. In some embodiments, the drive circuit in the peripheral region 101b does not include poly-silicon thin film transistor, and includes the oxide thin film transistor 102, and types of the transistors in the drive circuit is not limited in the embodiments of the present disclosure.

Referring to FIG. 5 to FIG. 7, each poly-silicon thin film transistor 1131 includes: a second gate electrode pattern 11311, and a source-drain electrode pattern 11312. The second gate electrode pattern 11311 and the plurality of scan lines 112 are disposed on a same layer. For example, the second gate electrode pattern 11311 and the plurality of scan lines 112 are manufactured by the same material and one patterning process. The source-drain electrode pattern 11312 and the plurality of data lines 104 of the array substrate are disposed on a same layer. For example, the source-drain electrode pattern 11312 and the plurality of data lines 104 are manufactured by the same material and one patterning process.

Referring to FIG. 5 to FIG. 7, each poly-silicon thin film transistor further includes: an active pattern 11313, and the array substrate further includes: a sixth insulation layer 114. The active pattern 11313 is disposed between the second gate electrode pattern 11311 and the base substrate 101, the sixth insulation layer 114 is disposed between the active pattern 11313 and the second gate electrode pattern 11311.

The source-drain electrode pattern 11312 is electrically connected to the active pattern 11313. The source-drain electrode pattern 11312 includes a source (S) electrode a1 and a drain (D) electrode a2. The source-drain electrode pattern 11312 being electrically connected to the active pattern 11313 indicates that the source electrode a1 is electrically connected to the active pattern 11313, and the drain electrode a2 is electrically connected to the active pattern 11313.

Referring to FIG. 5 to FIG. 7, the array substrate 10 further includes: a buffer layer 115. The buffer layer 115 is disposed between the base substrate 101 and the oxide thin film transistor 102, and a face of the buffer layer 115 is in contact with a face of the base substrate 101.

In summary, an array substrate is provided in the embodiments of the present disclosure. The array substrate includes a color filter layer, such that a distance between a light source on a side, distal from the color filter layer, of the base substrate and the color filter layer is less. Thus, light from the region of the color resist blocks is avoided being emitted from adjacent color resist blocks, and the cross color of the display panel is further avoided, such that the display effect of the display panel is great. In addition, the color resist block is at least partially overlapped with a second portion of the metal oxide pattern in the oxide thin film transistor, such that the overall footprint of the oxide thin film transistor and the color filter layer can be reduced, so as to acquire the display panel of high PPI.

FIG. 8 is a flowchart of a method for manufacturing an array substrate according to some embodiments of the present disclosure. Referring to FIG. 8, the method further includes the following steps.

In S201, a base substrate is provided.

A material of the base substrate 101 is glass, polyimide, or the like. Referring to FIG. 2, the base substrate 101 includes a display region 101a.

In S202, a plurality of oxide thin film transistors spaced apart from each other and a color filter layer are formed in the display region.

In the embodiments of the present disclosure, the plurality of oxide thin film transistors spaced apart from each other and the color filter layer are formed in the display region. Each of the plurality of oxide thin film transistors 102 includes a metal oxide pattern 1021. The metal oxide pattern 1021 includes a first portion 10211, a channel portion 10212, and a second portion 10213 that are sequentially connected. The first portion 10211 is configured to receive a data signal. The color filter layer 103 is disposed between the metal oxide pattern 1021 and the base substrate 101, and the color filter layer 103 includes a plurality of color resist blocks 1031 of different colors in one-to-one correspondence to the plurality of oxide thin film transistors 102. An orthogonal projection of each of the plurality of color resist blocks 1031 on the base substrate 101 is at least partially overlapped with an orthogonal projection of the second portion 10213 of the corresponding oxide thin film transistor 102 on the base substrate 101.

As the color resist block 1031 is at least partially overlapped with the second portion 10213 of the metal oxide pattern 1021, the overall footprint of the metal oxide pattern 1021 and the color resist block 1031 on the base substrate 101 can be reduced, so as to acquire the display panel of high PPI.

In some embodiments, colors of two adjacent color resist blocks 1031 of the plurality of color resist blocks 1031 in the color filter layer 103 are different. In the embodiments of the present disclosure, as the manufactured array substrate includes the color filter layer 103, a distance between a light source on a side, distal from the color filter layer 103, of the base substrate 101 and the color filter layer 103 is less. Thus, light from the region of the color resist blocks 1031 in the color filter layer 103 is avoided being emitted from adjacent color resist blocks 1031, and the cross color of the display panel is further avoided, such that the display effect of the display panel is ensured.

In summary, a method for manufacturing an array substrate is provided in the embodiments of the present disclosure. The manufactured array substrate includes a color filter layer, such that a distance between a light source on a side, distal from the color filter layer, of the base substrate and the color filter layer is less. Thus, light from the region of the color resist blocks is avoided being emitted from adjacent color resist blocks, and the cross color of the display panel is further avoided, such that the display effect of the display panel is great. In addition, the color resist block is at least partially overlapped with a second portion of the metal oxide pattern in the oxide thin film transistor, such that the overall footprint of the oxide thin film transistor and the color filter layer can be reduced, so as to acquire the display panel of high PPI.

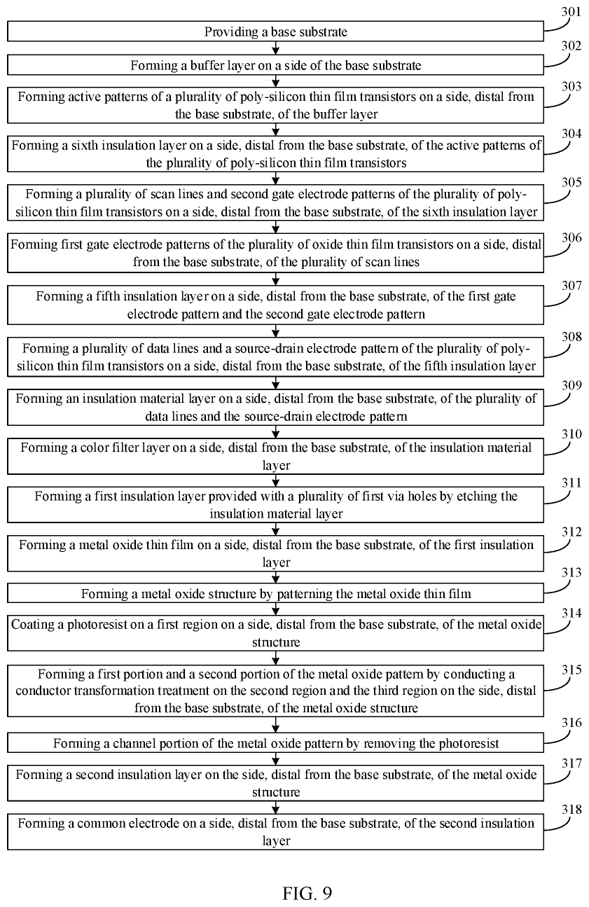

FIG. 9 is a flowchart of another method for manufacturing an array substrate according to some embodiments of the present disclosure. The method is applicable to manufacturing the array substrate in above embodiments, for example, the array substrate shown in FIG. 5. Referring to FIG. 9, the method further includes the following steps.

In S301, a base substrate is provided.

A material of the base substrate 101 is glass, polyimide, or the like. Referring to FIG. 2, the base substrate 101 includes a display region 101a and a peripheral region 101b on a side of the display region 101a. The peripheral region 101b in FIG. 2 is disposed on the left side of the display region 101a, and the peripheral region 101b is also disposed on the right side of the display region 101a, which is not limited in the embodiments of the present disclosure.

In S302, a buffer layer is formed on a side of the base substrate.

In the embodiments of the present disclosure, after the base substrate 101 is acquired, the buffer layer 115 is formed on the side of the base substrate 101. The function of the buffer layer 115 is to reduce the impact force of the base substrate 101 on other subsequently-formed film layers, so as to facilitate forming of other subsequently-formed film layers.

In S303, active patterns of a plurality of poly-silicon thin film transistors are formed on a side, distal from the base substrate, of the buffer layer.

In the embodiments of the present disclosure, after the buffer layer is formed, an active thin film is formed on the side, distal from the base substrate, of the buffer layer, and then the active thin film is crystallized. A patterned mask plate is disposed on a side, distal from the base substrate 101, of the crystallized active thin film, and the crystallized active thin film is patterned to acquire the active pattern 11313 of the plurality of poly-silicon thin film transistors. The patterning process includes: photoresist coating, exposing, developing, etching, and photoresist removing.

In some embodiments, a material of the active pattern is amorphous silicon (a-Si), and a material of the crystallized active thin film is low temperature ploy silicon (LTPS). The low temperature ploy silicon is also referred to as p-Si.

The plurality of poly-silicon thin film transistors function as the transistors in the drive circuit, that is, the drive circuit includes the plurality of poly-silicon thin film transistors. The plurality of poly-silicon thin film transistors are disposed in the peripheral region 101b. In some embodiments, the drive circuit in the peripheral region 101b includes poly-silicon thin film transistor, and the oxide thin film transistor 102. In some embodiments, the drive circuit in the peripheral region 101b merely includes the oxide thin film transistor 102, which is not limited in the embodiments of the present disclosure. The method for manufacturing the array substrate is illustrated by taking the transistor in the drive circuit being the poly-silicon thin film transistor, and the transistor in the display region 101a being the oxide thin film transistor 102 as an example in the embodiments of the present disclosure.

In S304, a sixth insulation layer is formed on a side, distal from the base substrate, of the active patterns of the plurality of poly-silicon thin film transistors.

In the embodiments of the present disclosure, after the active patterns 11313 of the plurality of poly-silicon thin film transistors are formed, the sixth insulation layer 114 is formed on the side, distal from the base substrate 101, of the active patterns 11313 of the plurality of poly-silicon thin film transistors. The sixth insulation layer 114 is also referred to as a gate electrode insulation layer.

In S305, a plurality of scan lines and second gate electrode patterns of the plurality of poly-silicon thin film transistors are formed on a side, distal from the base substrate, of the sixth insulation layer.

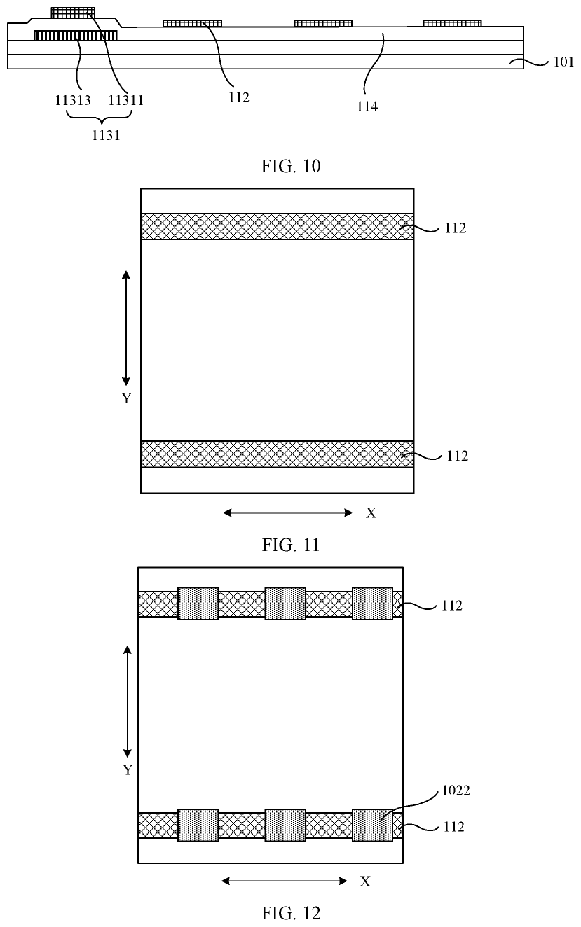

In the embodiments of the present disclosure, referring to FIG. 10, after the sixth insulation layer 114 is formed, the plurality of scan lines 112 and the second gate electrode patterns 11311 of the plurality of poly-silicon thin film transistors are formed on the side, distal from the base substrate 101, of the sixth insulation layer 114. That is, the plurality of scan lines 112 and the second gate electrode patterns 11311 of the plurality of poly-silicon thin film transistors are disposed on the same layer, and are formed by one patterning process. In some embodiments, materials of the plurality of scan lines 112 and the second gate electrode patterns 11311 of the plurality of poly-silicon thin film transistors include conductive materials, for example, metal materials.

In forming the plurality of scan lines 112 and the second gate electrode patterns 11311 of the plurality of poly-silicon thin film transistors, a first conduction thin film is formed on the side, distal from the base substrate 101, of the sixth insulation layer 114, a patterned mask plate is disposed on a side, distal from the base substrate 101, of the first conduction thin film, and the first conduction thin film is patterned to acquire the plurality of scan lines 112 and the second gate electrode pattern 11311 of the poly-silicon thin film transistor. The patterned mask plate used in patterning the first conduction thin film and the patterned mask plate used in patterning the crystallized active thin film are different.

As the plurality of scan lines 112 and the second gate electrode patterns 11311 of the plurality of poly-silicon thin film transistors are formed by one patterning process, the plurality of scan lines 112 and the second gate electrode patterns 11311 of the plurality of poly-silicon thin film transistors are acquired by one patterned mask plate, such that a number of the mask plates required for manufacturing the array substrate is reduced, and the manufacturing cost is reduced.

FIG. 11 is a schematic diagram of scan lines according to some embodiments of the present disclosure. Referring to FIG. 11, the plurality of scan lines 112 are disposed in the display region 101a of the base substrate 101, and extend in the pixel row direction X. FIG. 11 shows two scan lines 112.

The plurality of scan lines 112 are configured to provide the scan signal to the oxide thin film transistor 102 subsequently-formed in the display region 101a. For example, the drive circuit in the peripheral region 101b are connected to the plurality of scan lines 112, and the drive circuit provides the scan signal to the subsequently-formed oxide thin film transistor 102 through the plurality of scan lines 112.

In some embodiments, a length of the scan line 112 in the pixel column direction Y (that is, the width of the scan line 112) ranges from 1.5 μm to 2.5 μm, for example, 1.8 μm.

In S306, first gate electrode patterns of the plurality of oxide thin film transistors are formed on a side, distal from the base substrate, of the plurality of scan lines.

In the embodiments of the present disclosure, material of the first gate electrode patterns 1022 of the plurality of oxide thin film transistors 102 include conductive materials, such as, metal materials. After the plurality of scan lines 112 are formed, first gate electrode thin films are formed on the side, distal from the base substrate 101, of the plurality of scan lines 112, a patterned mask plate is disposed on a side, distal from the base substrate 101, of the first gate electrode thin films, and the first gate electrode thin films are patterned to acquire the first gate electrode patterns 1022 of the plurality of oxide thin film transistors 102. The patterned mask plates used in patterning different thin films are different. For example, the patterned mask plate used in patterning the first gate electrode thin film are different from the patterned mask plate used in patterning the first conduction thin film and the patterned mask plate used in patterning the crystallized active thin film.

FIG. 12 is a schematic diagram of forming a first gate electrode pattern according to some embodiments of the present disclosure. Referring to FIG. 12, the length, in the pixel column direction Y, of the orthogonal projection of the first gate electrode pattern 1022 on the base substrate 101 is greater than the length, in the pixel column direction Y, of an orthogonal projection of the scan line 112 on the base substrate 101, such that the orthogonal projection of the first gate electrode pattern 1022 on the base substrate 101 covers the orthogonal projection of the channel portion 10212 of the subsequently-formed metal oxide pattern 1021 on the base substrate 101. The pixel column direction Y is perpendicular to the pixel row direction X.

In S307, a fifth insulation layer is formed on a side, distal from the base substrate, of the first gate electrode pattern and the second gate electrode pattern.

In the embodiments of the present disclosure, after the first gate electrode pattern 1022 is formed, the fifth insulation layer 111 is formed on a side, distal from the base substrate 101, of the first gate electrode pattern 1022 and the second gate electrode pattern 11311. an orthogonal projection of the fifth insulation layer 111 on the base substrate 101 covers orthogonal projections of the first gate electrode patterns 1022 of the plurality of oxide thin film transistors 102 on the base substrate 101, and orthogonal projections of the second gate electrode patterns 11311 of the plurality of poly-silicon thin film transistors 1131 on the base substrate 101.

In some embodiments, the fifth insulation layer 111 is also referred to as an inter-layer dielectric (ILD). A material of the fifth insulation layer 111 includes at least one of silicon dioxide and silicon nitride. The fifth insulation layer 111 is not shown in a top view as the fifth insulation layer 111 completely covers the base substrate 101.

In S308, a plurality of data lines and a source-drain electrode pattern of the plurality of poly-silicon thin film transistors are formed on a side, distal from the base substrate, of the fifth insulation layer.

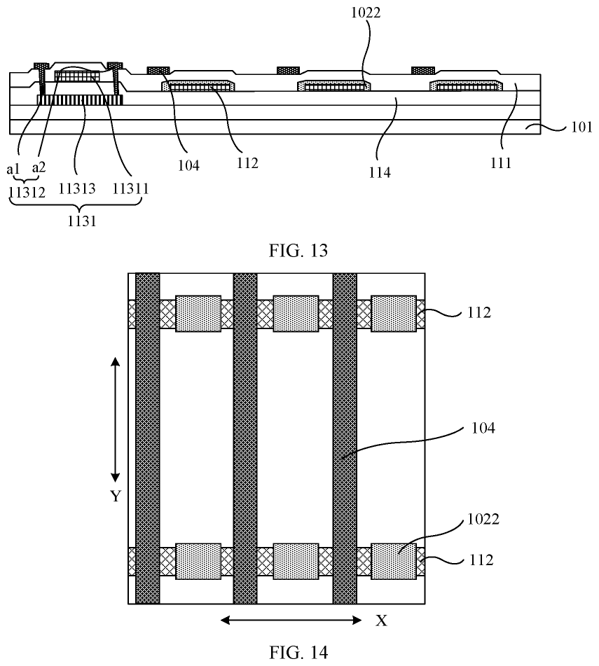

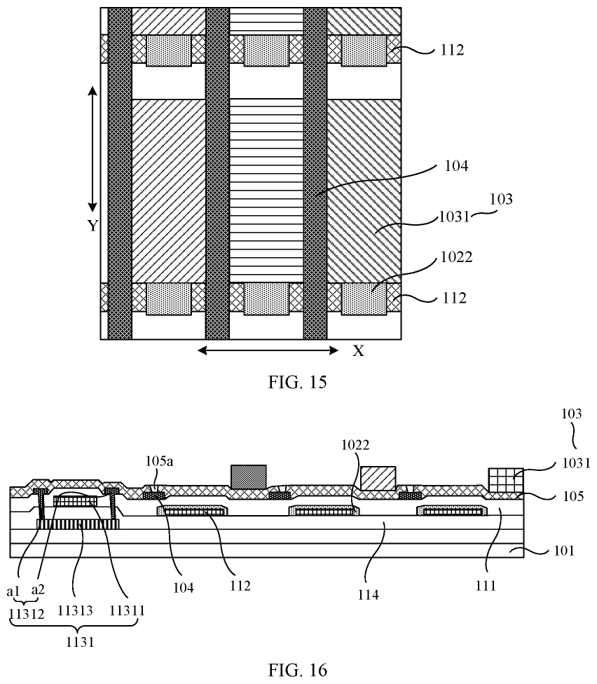

In the embodiments of the present disclosure, referring to FIG. 13, after the fifth insulation layer 111 is formed, the plurality of data lines 104 and the source-drain electrode pattern 11312 of the plurality of poly-silicon thin film transistors 1131 are formed on the side, distal from the base substrate 101, of the fifth insulation layer 111. That is, the plurality of data lines 104 and the source-drain electrode pattern 11312 of the plurality of poly-silicon thin film transistors 1131 are disposed on the same layer and are formed by one patterning process. In some embodiments, materials of the plurality of data lines 104 and the source-drain electrode pattern 11312 of the plurality of poly-silicon thin film transistors 1131 include conductive materials, for example, metal materials.

In forming the plurality of data lines 104 and the source-drain electrode pattern 11312 of the plurality of poly-silicon thin film transistors 1131, a second conduction thin film is formed on the side, distal from the base substrate 101, of the fifth insulation layer 111, a patterned mask plate is disposed on a side, distal from the base substrate 101, of the second conduction thin film, and the second conduction thin film is patterned to acquire the plurality of data lines 104 and the source-drain electrode pattern 11312 of the plurality of poly-silicon thin film transistors 1131.

As the plurality of data lines 104 and the source-drain electrode pattern 11312 of the plurality of poly-silicon thin film transistors 1131 are formed by one patterning process, the plurality of data lines 104 and the source-drain electrode pattern 11312 of the plurality of poly-silicon thin film transistors 1131 are acquired by one patterned mask plate, such that the number of the mask plates required for manufacturing the array substrate is reduced, and the manufacturing cost is reduced.

FIG. 14 is a schematic diagram of forming a data line according to some embodiments of the present disclosure. Referring to FIG. 14, the plurality of data lines 104 are disposed in the display region 101a of the base substrate 101, and extend in the pixel column direction Y. The plurality of data lines 104 are configured to provide the data line to the first portion 10211 of the metal oxide pattern 1021 of the oxide thin film transistor 102 subsequently-formed in the display region 101a.

In the embodiments of the present disclosure, the source-drain electrode pattern 11312 of the poly-silicon thin film transistor 1131 is electrically connected to the active pattern 11313. For example, the source-drain electrode pattern 11312 of the poly-silicon thin film transistor 1131 includes the source electrode a1 and the drain electrode a2 that are spaced apart from each other, and both the fifth insulation layer 111 and the sixth insulation layer 114 are provided with a third via hole and a fourth via hole. The source electrode a1 is electrically connected to the active pattern 11313 via the third via hole, and the drain electrode a2 is electrically connected to the active pattern 11313 via the fourth via hole.

In S309, an insulation material layer is formed on a side, distal from the base substrate, of the plurality of data lines and the source-drain electrode pattern.

In the embodiments of the present disclosure, after the plurality of data lines 104 and the source-drain electrode pattern 11312 are formed, the insulation material layer c is formed on the side, distal from the base substrate 101, of the plurality of data lines 104 and the source-drain electrode pattern 11312. A material of the insulation material layer includes insulation material layer (SiO₂). The insulation material layer is not shown in a top view as the insulation material layer completely covers the base substrate 101.

In S310, a color filter layer is formed on a side, distal from the base substrate, of the insulation material layer.

In the embodiments of the present disclosure, after the insulation material layer is formed, the color filter layer 103 is formed on the side, distal from the base substrate 101, of the insulation material layer. The color filter layer 103 includes a plurality of color resist blocks 1031 of different colors in one-to-one correspondence to the plurality of oxide thin film transistors 102. Each of the plurality of color resist blocks 1031 is configured used to transmit light of corresponding color.

In some embodiments, the color filter layer 103 includes a plurality of red color resist blocks, a plurality of green color resist blocks, and a plurality of blue color resist blocks. The plurality of red color resist blocks are used to transmit red light, the plurality of green color resist blocks are used to transmit green light, and plurality of blue color resist blocks are used to transmit blue light.

In the embodiments of the present disclosure, the plurality of red color resist blocks in the color filter layer 103 are formed by one patterning process, the plurality of green color resist blocks in the color filter layer 103 are formed by one patterning process, the plurality of blue color resist blocks in the color filter layer 103 are formed by one patterning process. In addition, the color resist blocks of different colors are formed by different patterning processes. That is, the plurality of red color resist blocks, the plurality of green color resist blocks, and the plurality of blue color resist blocks are formed by three patterning processes respectively.

In some embodiments, in forming the color resist block 1031 of each color, a color resist thin film of the color is entirely covered, a patterned mask plate is disposed on a side, distal from the base substrate 101, of the color resist thin film, and the color resist thin film is patterned to acquire a plurality of color resist blocks of the color. The patterned mask plates for forming the color resist blocks of different colors are different.

As the color resist blocks 1031 of three colors are formed by three patterning processes respectively, thicknesses of color resist blocks 1031 of three colors are different, such that displays by the sub-pixels of different colors in the display panel are different. Thus, after the array substrate are manufactured subsequently, in the process of debugging the product, luminance of the sub-pixels is adjusted by adjusting the drive voltages provided to the sub-pixels of different colors, the display correction is further performed by the optical alignment.

Each pixel in the display panel includes: a pixel circuit. The oxide thin film transistors 102 in the array substrate 10 is taken as the transistor in the pixel circuit of the sub-pixel. That is, the oxide thin film transistors 102 in the array substrate 10 is disposed in the display region 101a of the base substrate 101. In addition, each sub-pixel includes one color resist block 1031 to emit light of the color corresponding to the color resist block 1031.

In S311, a first insulation layer provided with a plurality of first via holes is formed by etching the insulation material layer.

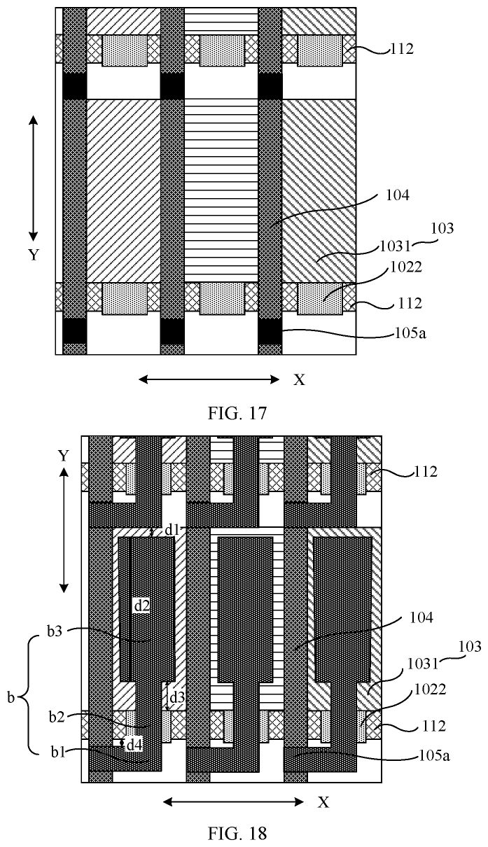

As the display region 101a of the array substrate includes a plurality of oxide thin film transistors 102, referring to FIG. 16 and FIG. 17, the first insulation layer 105 provided with the plurality of first via holes 105a is formed by etching the insulation material layer. The etching process for etching the insulation material layer is a wet etching process, or a dry etching process. Each first via hole 105a in the first insulation layer 105 is configured to expose at least part of one data line 104.

In the embodiments of the present disclosure, in FIG. 17, the first via hole 105a is shown by a filled pattern to facilitate showing the first via hole 105a in the first insulation layer 105. The region including materials in the first insulation layer 105 is shown by other region without filled pattern.

In S312, a metal oxide thin film is formed on a side, distal from the base substrate, of the first insulation layer.

In the embodiments of the present disclosure, after the first insulation layer 105 is formed, the metal oxide thin film is formed on a side, distal from the base substrate, of the first insulation layer with a metal oxide material. A material of the metal oxide thin film includes the metal oxide.

In S313, a metal oxide structure is formed by patterning the metal oxide thin film.

In the embodiments of the present disclosure, after the metal oxide thin film is formed, a patterned mask plate is disposed on a side, distal from the base substrate 101, of the metal oxide thin film, and the metal oxide structure is formed by patterning the metal oxide thin film. For example, referring to FIG. 18, a plurality of metal oxide structures b are formed. The patterned mask plates used in patterning different thin films are different in the embodiments of the present disclosure.

In some embodiments, referring to FIG. 18, a distance d1, in the pixel column direction Y, between two adjacent metal oxide structures b is 2.5 μm. A distance d4, in the pixel column direction Y, between a first region b1 of the metal oxide structure and the scan line 112 is 0.9 μm. A third region b3 of the metal oxide structure includes a first sub-region and a second sub-region, and a length of the first sub-region in the pixel row direction X is greater than a length of the second sub-region in the pixel row direction X. In some embodiments, the length of the first sub-region in the pixel column direction Y is 9.6 μm, and a distance d3, in the pixel column direction Y, between the second sub-region and the scan line 112 is 0.9 μm. That is, d3 is equal to d4. In some embodiments, d3 is not equal to d4, which is not limited in the embodiments of the present disclosure.

In S314, a photoresist is coated on a first region on a side, distal from the base substrate, of the metal oxide structure.

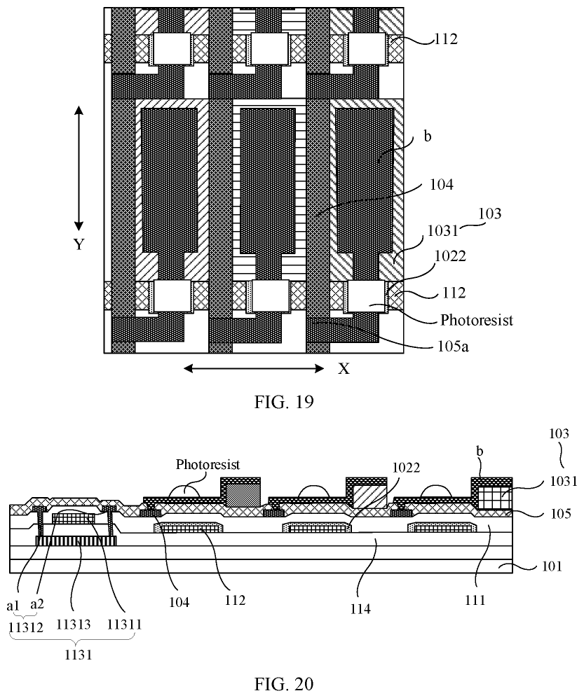

Referring to FIG. 19 and FIG. 20, an orthogonal projection of the coated photoresist on the base substrate 101 falls within the orthogonal projection of the first gate electrode pattern 1022 on the base substrate 101. The side, distal from the base substrate 101, of the metal oxide structure b further includes a second region b2 and a third region b3, and the second region b2 and the third region b3 are respectively disposed on two sides of the first region b1.

In S315, a first portion and a second portion of the metal oxide pattern are formed by conducting a conductor transformation treatment on the second region and the third region on the side, distal from the base substrate, of the metal oxide structure.

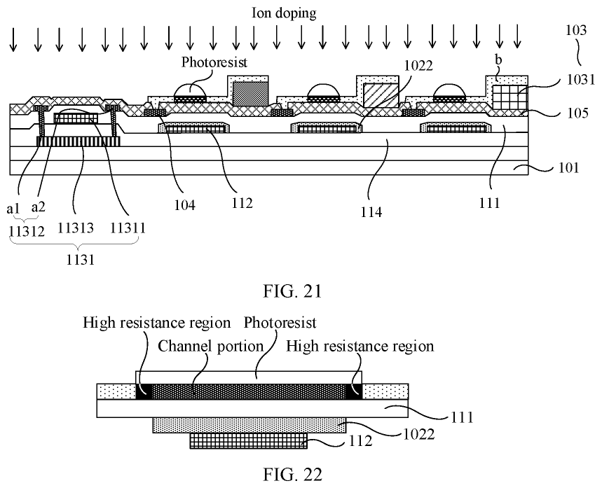

In the embodiments of the present disclosure, after the photoresist is coated on the first region b1, referring to FIG. 21, ions are implanted into the metal oxide structure b (that is, ion-doping), so as to acquire the first portion 10211 and the second portion 10213 of the metal oxide pattern 1021 by conducting the conductor transformation treatment on the second region b2 and the third region b3 that are not coated with the photoresist. In some embodiments, the implanted ion is boron ion or phosphorus ion.

In the case that an area of the orthogonal projection of coated photoresist in S314 on the base substrate 101 is greater than an area of the orthogonal projection of the first gate electrode pattern 1022 on the base substrate 101, referring to FIG. 22, after the conducting process is performed on the second region b2 and the third region b3, some regions are not conducted other than the channel portion. In this case, a high resistance region is formed when the oxide thin film transistor operates, such that the property of the oxide thin film transistor is affected.

Thus, in the embodiments of the present disclosure, the area of the orthogonal projection of coated photoresist in S314 on the base substrate 101 falls within the area of the orthogonal projection of the first gate electrode pattern 1022 on the base substrate 101, such that the oxide thin film transistor operates normally, and the property of the oxide thin film transistor is ensured.

In S316, a channel portion of the metal oxide pattern is formed by removing the photoresist.

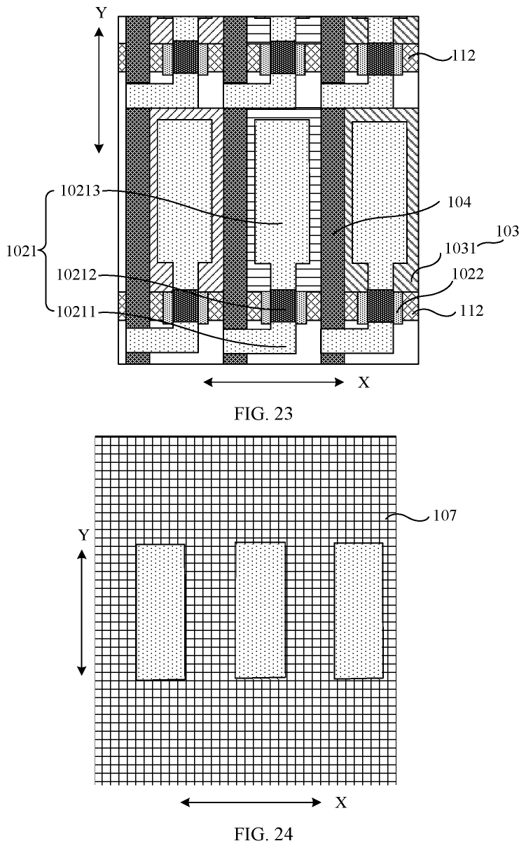

In the embodiments of the present disclosure, referring to FIG. 23, after the conducting process is performed on the second region b2 and the third region b3 that are disposed on the side, distal from the base substrate 101, of the metal oxide structure, the channel portion 10212 of the metal oxide pattern 1021 is acquired by removing the photoresist on the first region on the side, distal from the base substrate 101, of the metal oxide structure b. That is, the metal oxide pattern 1021 of the oxide thin film transistor 102 is acquired.

In S317, a second insulation layer is formed on the side, distal from the base substrate, of the metal oxide structure.

In the embodiments of the present disclosure, after the metal oxide pattern 1021 is formed, the second insulation layer 106 is formed on the side, distal from the base substrate 101, of the metal oxide structure 1021. The second insulation layer 106 includes a second passivation layer 1061 and a planarization layer 1062.

Referring to FIG. 5, a face, distal from the base substrate 101, of the section of the second passivation layer 1061 covering the color resist block 1031 is coplanar with a face, distal from the base substrate 101, of the planarization layer 1062. In some embodiments, the face, distal from the base substrate 101, of the section of the second passivation layer 1061 covering the color resist block 1031 is not coplanar with the face, distal from the base substrate 101, of the planarization layer 1062. For example, a distance between the face, distal from the base substrate 101, of the planarization layer 1062 and the base substrate 101 is greater than a distance between the face, distal from the base substrate 101, of the section of the second passivation layer 1061 covering the color resist block 1031, which is not limited in the embodiments of the present disclosure.

In some embodiments, as each the second passivation layer 1061 and the planarization layer 1062a complete cover, the second passivation layer 1061 and the planarization layer 1062a are not shown in a top view. A thickness of the planarization layer 1062a ranges from 1 μm to 2 μm.

In S318, a common electrode is formed on a side, distal from the base substrate, of the second insulation layer.

In the embodiments of the present disclosure, referring to FIG. 23, after the second insulation layer 106 is formed, the common electrode 107 is formed on the side, distal from the base substrate 101, of the second insulation layer 106. An orthogonal projection of the common electrode 107 on the base substrate 101 is at least partially overlapped with the orthogonal projection of the second portion 10213 of the metal oxide pattern 1021 on the base substrate 101, and the second portion 10213 is taken as a pixel electrode to drive, with the common electrode, liquid crystals to be deflected.

It should be noted that the sequence of the steps in the method for manufacturing the array substrate in the embodiments of the present disclosure may be adjusted appropriately, and the steps may be added or deleted as required. For example, S302 to S309, S311, and S317 to S308 may be deleted as required, S311 may be performed before S310. Any method change made within the technical scope disclosed in the present disclosure by the person skilled in the art should be included within the scope of protection of the present disclosure, and thus is not described in detail herein.

In summary, a method for manufacturing an array substrate is provided in the embodiments of the present disclosure. The manufactured array substrate includes a color filter layer, such that a distance between a light source on a side, distal from the color filter layer, of the base substrate and the color filter layer is less. Thus, light from the region of the color resist blocks is avoided being emitted from adjacent color resist blocks, and the cross color of the display panel is further avoided, such that the display effect of the display panel is great. In addition, the color resist block is at least partially overlapped with a second portion of the metal oxide pattern in the oxide thin film transistor, such that the overall footprint of the oxide thin film transistor and the color filter layer can be reduced, so as to acquire the display panel of high PPI.

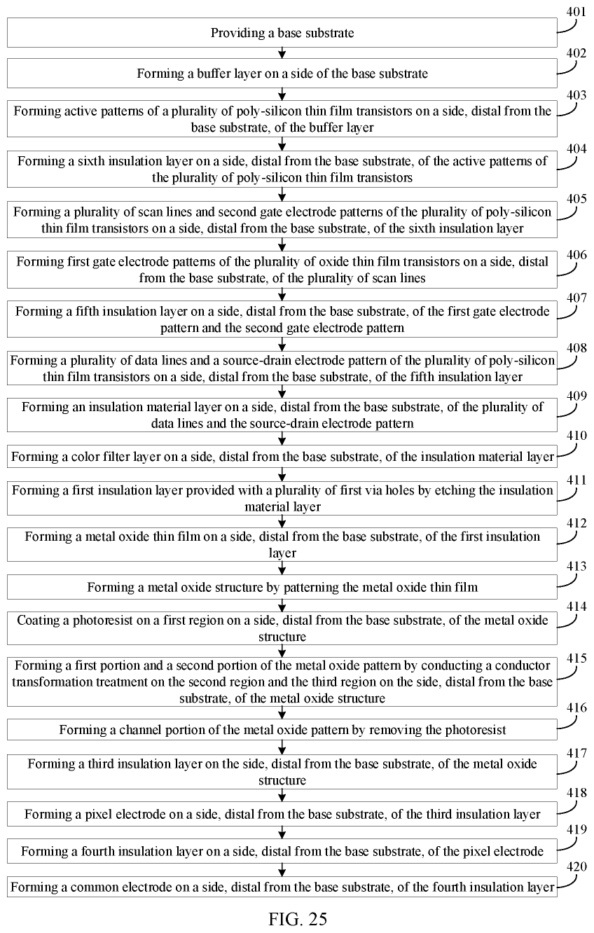

FIG. 25 is a flowchart of another method for manufacturing an array substrate according to some embodiments of the present disclosure. The method is applicable to manufacturing the array substrate in above embodiments, for example, the array substrate shown in FIG. 7. Referring to FIG. 25, the method further includes the following steps.

In S401, a base substrate is provided.

In the embodiments of the present disclosure, detailed description of S401 is referred to the description of S301, and thus is not repeated herein in the embodiments of the present disclosure.

In S402, a buffer layer is formed on a side of the base substrate.

In the embodiments of the present disclosure, detailed description of S402 is referred to the description of S302, and thus is not repeated herein in the embodiments of the present disclosure.

In S403, active patterns of a plurality of poly-silicon thin film transistors are formed on a side, distal from the base substrate, of the buffer layer.

In the embodiments of the present disclosure, detailed description of S403 is referred to the description of S303, and thus is not repeated herein in the embodiments of the present disclosure.

In S404, a sixth insulation layer is formed on a side, distal from the base substrate, of the active patterns of the plurality of poly-silicon thin film transistors.

In the embodiments of the present disclosure, detailed description of S404 is referred to the description of S304, and thus is not repeated herein in the embodiments of the present disclosure.

In S405, a plurality of scan lines and second gate electrode patterns of the plurality of poly-silicon thin film transistors are formed on a side, distal from the base substrate, of the sixth insulation layer.

In the embodiments of the present disclosure, detailed description of S405 is referred to the description of S305, and thus is not repeated herein in the embodiments of the present disclosure.

In S406, first gate electrode patterns of the plurality of oxide thin film transistors are formed on a side, distal from the base substrate, of the plurality of scan lines.

In the embodiments of the present disclosure, detailed description of S406 is referred to the description of S306, and thus is not repeated herein in the embodiments of the present disclosure.

In S407, a fifth insulation layer is formed on a side, distal from the base substrate, of the first gate electrode pattern and the second gate electrode pattern.

In the embodiments of the present disclosure, detailed description of S407 is referred to the description of S307, and thus is not repeated herein in the embodiments of the present disclosure.

In S408, a plurality of data lines and a source-drain electrode pattern of the plurality of poly-silicon thin film transistors are formed on a side, distal from the base substrate, of the fifth insulation layer.

In the embodiments of the present disclosure, detailed description of S408 is referred to the description of S308, and thus is not repeated herein in the embodiments of the present disclosure.

In S409, an insulation material layer is formed on a side, distal from the base substrate, of the plurality of data lines and the source-drain electrode pattern.

In the embodiments of the present disclosure, detailed description of S409 is referred to the description of S309, and thus is not repeated herein in the embodiments of the present disclosure.

In S410, a color filter layer is formed on a side, distal from the base substrate, of the insulation material layer.

In the embodiments of the present disclosure, detailed description of S410 is referred to the description of S310, and thus is not repeated herein in the embodiments of the present disclosure.

In S411, a first insulation layer provided with a plurality of first via holes is formed by etching the insulation material layer.

In the embodiments of the present disclosure, detailed description of S411 is referred to the description of S311, and thus is not repeated herein in the embodiments of the present disclosure.

In S412, a metal oxide thin film is formed on a side, distal from the base substrate, of the first insulation layer.

In the embodiments of the present disclosure, detailed description of S412 is referred to the description of S312, and thus is not repeated herein in the embodiments of the present disclosure.

In S413, a metal oxide structure is formed by patterning the metal oxide thin film.

In the embodiments of the present disclosure, detailed description of S413 is referred to the description of S313, and thus is not repeated herein in the embodiments of the present disclosure. In addition, as the metal oxide pattern in the array substrate 10 manufactured by the method does not function as the pixel electrode, an area of the orthogonal projection, on the base substrate 101, of the metal oxide structure formed in S413 and used to form the metal oxide pattern is less than an area of the orthogonal projection, on the base substrate 101, of the metal oxide structure formed in S313 and used to form the metal oxide pattern.

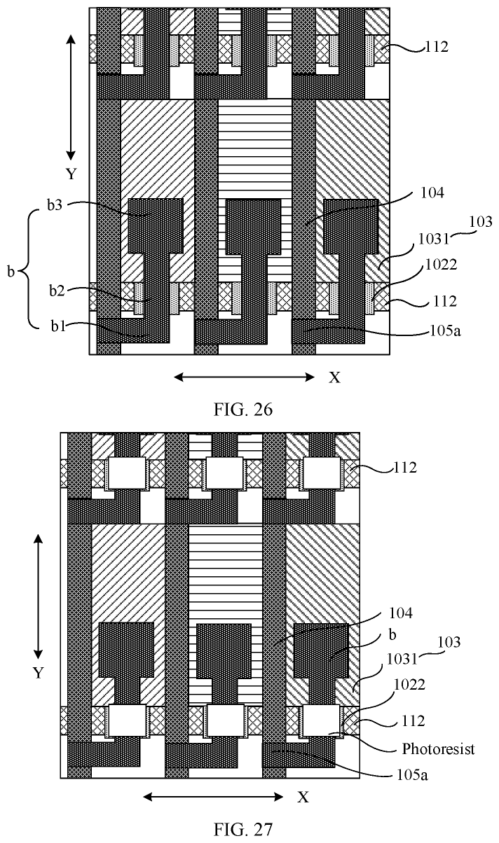

In some embodiments, referring to FIG. 26, a length, in the pixel column direction Y, of the metal oxide structure b is less, and it is merely necessary to electrically connect the subsequently-formed pixel electrode to the second portion of the metal oxide pattern.

In S414, a photoresist is coated on a first region on a side, distal from the base substrate, of the metal oxide structure.

In the embodiments of the present disclosure, referring to FIG. 27, an orthogonal projection of the coated photoresist on the base substrate 101 falls within the orthogonal projection of the first gate electrode pattern 1022 on the base substrate 101. The side, distal from the base substrate 101, of the metal oxide structure b further includes a second region b2 and a third region b3, and the second region b2 and the third region b3 are respectively disposed on two sides of the first region b1.

In S415, a first portion and a second portion of the metal oxide pattern are formed by conducting a conductor transformation treatment on the second region and the third region on the side, distal from the base substrate, of the metal oxide structure.

Detailed description of S415 is referred to the description of S315, and thus is not repeated herein in the embodiments of the present disclosure.

In S416, a channel portion of the metal oxide pattern is formed by removing the photoresist.

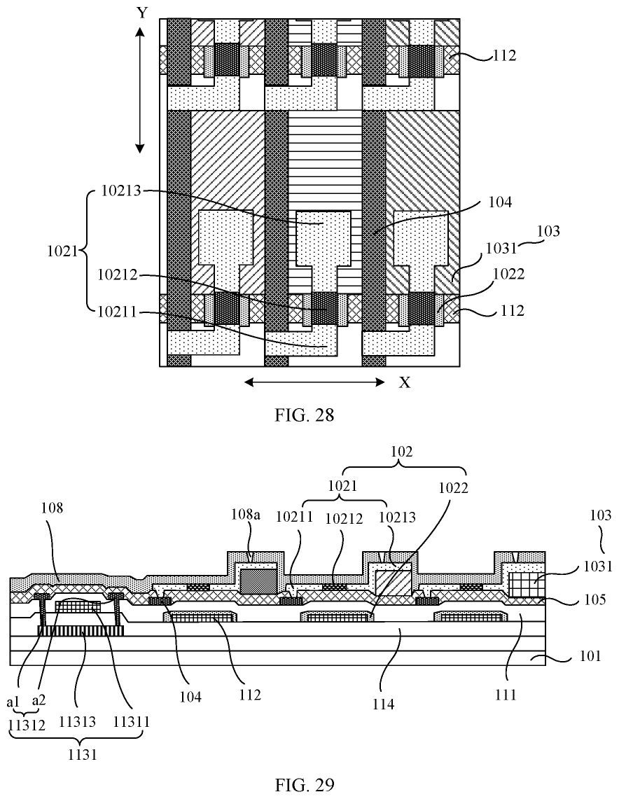

FIG. 28 is a schematic diagram of forming a metal oxide pattern according to some embodiments of the present disclosure. In addition, detailed description of S416 is referred to the description of S316, and thus is not repeated herein in the embodiments of the present disclosure.

In S417, a third insulation layer is formed on the side, distal from the base substrate, of the metal oxide structure.

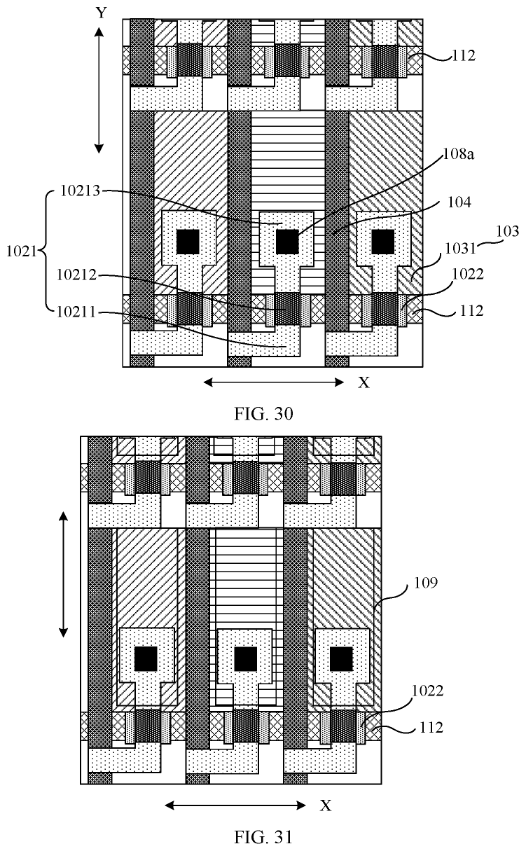

In the embodiments of the present disclosure, referring to FIG. 29 and FIG. 30, after the metal oxide pattern 1021 is formed, the third insulation layer 108 is formed on the side, distal from the base substrate 101, of the metal oxide structure 1021. The third insulation layer 108 is a passivation (PVX) layer. In some embodiments, a material of the third insulation layer 108 includes silicon dioxide.

Referring to FIG. 29, the third insulation layer 108 is in contact with the second portion 10213, and the third insulation layer 108 is provided with a plurality of second via hole 108a. Each of the plurality of second via holes 108a is configured to expose at least part of the second portion 10213 of one oxide thin film transistor 102.

In the embodiments of the present disclosure, in FIG. 28, the second via hole 108a is shown by a filled pattern to facilitate showing the second via hole 108a in the third insulation layer 108. The region including materials in the third insulation layer 108 is shown by other region without filled pattern.

In S418, a pixel electrode is formed on a side, distal from the base substrate, of the third insulation layer.

In the embodiments of the present disclosure, referring to FIG. 31, after the third insulation layer 108 is formed, the pixel electrode 109 is formed on the side, distal from the base substrate 101, of the third insulation layer 108. An orthogonal projection of the pixel electrode 109 on the base substrate 101 is at least partially overlapped with the orthogonal projection of the second via hole 108a on the base substrate 101, and the pixel electrode 109 is electrically connected to the second portion 10213 of the oxide thin film transistor 102 via the second via hole 108a.

In S419, a fourth insulation layer is formed on a side, distal from the base substrate, of the pixel electrode.

In the embodiments of the present disclosure, after the pixel electrode 109 is formed, the fourth insulation layer 110 is formed on the side, distal from the base substrate 101, of the pixel electrode 109. The fourth insulation layer 110 is a planarization layer (PLN), and the planarization layer is used to planarize the side, with the film layers, of the base substrate 101.

In S420, a common electrode is formed on a side, distal from the base substrate, of the fourth insulation layer.

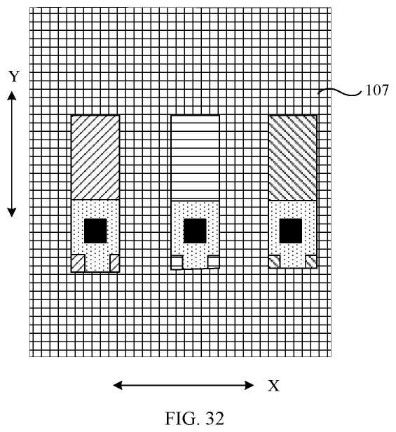

In the embodiments of the present disclosure, referring to FIG. 32, after the fourth insulation layer is formed, the common electrode 107 is formed on the side, distal from the base substrate 101, of the fourth insulation layer 110. An orthogonal projection of the common electrode 107 on the base substrate 101 is at least partially overlapped with the orthogonal projection of the pixel electrode 109 on the base substrate 101. The pixel electrode 109, with the common electrode 107, is used to drive liquid crystals to be deflected.

It should be noted that the sequence of the steps in the method for manufacturing the array substrate in the embodiments of the present disclosure may be adjusted appropriately, and the steps may be added or deleted as required. For example, S402 to S409, S411, and S417 to S418 may be deleted as required, S411 may be performed before S410. Any method change made within the technical scope disclosed in the present disclosure by the person skilled in the art should be included within the scope of protection of the present disclosure, and thus is not described in detail herein.

In summary, a method for manufacturing an array substrate is provided in the embodiments of the present disclosure. The manufactured array substrate includes a color filter layer, such that a distance between a light source on a side, distal from the color filter layer, of the base substrate and the color filter layer is less. Thus, light from the region of the color resist blocks is avoided being emitted from adjacent color resist blocks, and the cross color of the display panel is further avoided, such that the display effect of the display panel is great. In addition, the color resist block is at least partially overlapped with a second portion of the metal oxide pattern in the oxide thin film transistor, such that the overall footprint of the oxide thin film transistor and the color filter layer can be reduced, so as to acquire the display panel of high PPI.

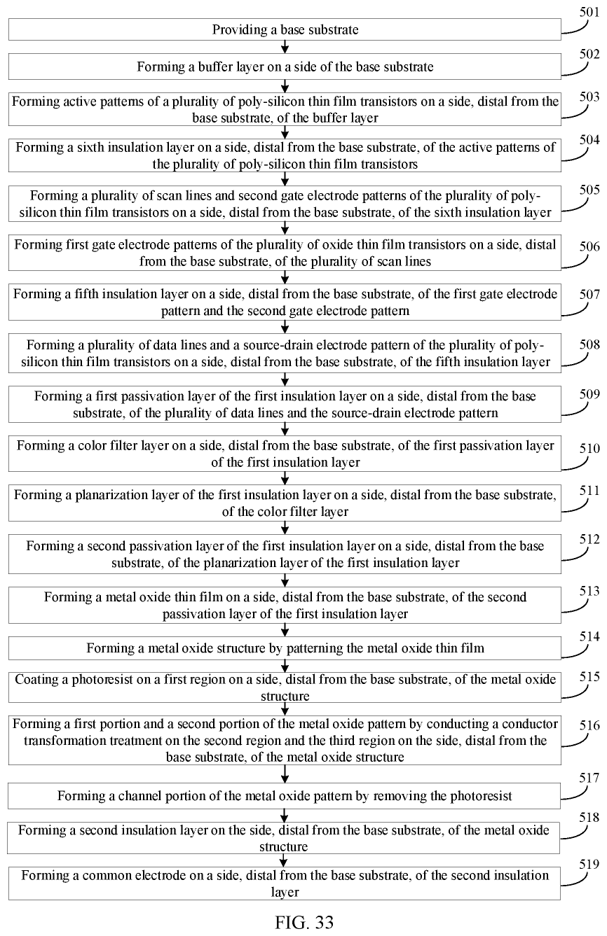

FIG. 33 is a flowchart of another method for manufacturing an array substrate according to some embodiments of the present disclosure. The method is applicable to manufacturing the array substrate in above embodiments, for example, the array substrate shown in FIG. 6. Referring to FIG. 33, the method further includes the following steps.

In S501, a base substrate is provided.

In the embodiments of the present disclosure, detailed description of S501 is referred to the description of S301, and thus is not repeated herein in the embodiments of the present disclosure.

In S502, a buffer layer is formed on a side of the base substrate.

In the embodiments of the present disclosure, detailed description of S502 is referred to the description of S302, and thus is not repeated herein in the embodiments of the present disclosure.

In S503, active patterns of a plurality of poly-silicon thin film transistors are formed on a side, distal from the base substrate, of the buffer layer.

In the embodiments of the present disclosure, detailed description of S503 is referred to the description of S303, and thus is not repeated herein in the embodiments of the present disclosure.

In S504, a sixth insulation layer is formed on a side, distal from the base substrate, of the active patterns of the plurality of poly-silicon thin film transistors.

In the embodiments of the present disclosure, detailed description of S504 is referred to the description of S304, and thus is not repeated herein in the embodiments of the present disclosure.

In S505, a plurality of scan lines and second gate electrode patterns of the plurality of poly-silicon thin film transistors are formed on a side, distal from the base substrate, of the sixth insulation layer.

In the embodiments of the present disclosure, detailed description of S505 is referred to the description of S305, and thus is not repeated herein in the embodiments of the present disclosure.

In S506, first gate electrode patterns of the plurality of oxide thin film transistors are formed on a side, distal from the base substrate, of the plurality of scan lines.

In the embodiments of the present disclosure, detailed description of S506 is referred to the description of S306, and thus is not repeated herein in the embodiments of the present disclosure.

In S507, a fifth insulation layer is formed on a side, distal from the base substrate, of the first gate electrode pattern and the second gate electrode pattern.

In the embodiments of the present disclosure, detailed description of S507 is referred to the description of S307, and thus is not repeated herein in the embodiments of the present disclosure.

In S508, a plurality of data lines and a source-drain electrode pattern of the plurality of poly-silicon thin film transistors are formed on a side, distal from the base substrate, of the fifth insulation layer.

In the embodiments of the present disclosure, detailed description of S508 is referred to the description of S308, and thus is not repeated herein in the embodiments of the present disclosure.

In S509, a first passivation layer of the first insulation layer is formed on a side, distal from the base substrate, of the plurality of data lines and the source-drain electrode pattern.

In the embodiments of the present disclosure, after the plurality of data lines and the source-drain electrode pattern are formed, the first passivation layer 1051 of the first insulation layer 105 is formed on the side, distal from the base substrate, of the plurality of data lines and the source-drain electrode pattern.

In S510, a color filter layer is formed on a side, distal from the base substrate, of the first passivation layer of the first insulation layer.

In the embodiments of the present disclosure, detailed description of S510 is referred to the description of S310, and thus is not repeated herein in the embodiments of the present disclosure.

In S511, a planarization layer of the first insulation layer is formed on a side, distal from the base substrate, of the color filter layer.

After the color filter layer 103 is formed, the planarization layer 1052 of the first insulation layer 105 is formed on the side, distal from the base substrate 101, of the color filter layer to planarize the film layers on the base substrate 101.

In S512, a second passivation layer of the first insulation layer is formed on a side, distal from the base substrate, of the planarization layer of the first insulation layer.

In the embodiments of the present disclosure, for preventing hydrogen in the planarization layer 1052 diffusing to the channel portion of the subsequently-formed metal oxide pattern to conduct the channel portion in the subsequently annealing process, the second passivation layer 1053 of the first insulation layer 105 is formed on the side, distal from the base substrate 101, of the planarization layer 1052 after the planarization layer 1052 of the first insulation layer 105 is formed. The second passivation layer 1053 does not contain hydrogen, and thus does not affect the channel portion of the metal oxide pattern.

Referring to FIG. 34, the first insulation layer 105 is provided with a plurality of first via holes 105a, and each of the plurality of first via holes 105a is configured to expose at least part of one data line 104, such that the first portion 10211 of the subsequently-formed metal oxide pattern 1021 is electrically connected to the data line 104 via the first via hole 105a. As the first insulation layer 105 includes a first passivation layer 1051, a planarization layer 1052, and a second passivation layer 1053, the first passivation layer 1051, the planarization layer 1052, and the second passivation layer 1053 are provided with a plurality of first via holes 105a.

In S513, a metal oxide thin film is formed on a side, distal from the base substrate, of the second passivation layer of the first insulation layer.

After the second passivation layer is formed, the metal oxide thin film is formed on the side, distal from the base substrate 101, of the second passivation layer. A material of the metal oxide thin film includes the metal oxide.

In S514, a metal oxide structure is formed by patterning the metal oxide thin film.

In the embodiments of the present disclosure, detailed description of S514 is referred to the description of S313, and thus is not repeated herein in the embodiments of the present disclosure.

In S515, a photoresist is coated on a first region on a side, distal from the base substrate, of the metal oxide structure.

In the embodiments of the present disclosure, detailed description of S515 is referred to the description of S314, and thus is not repeated herein in the embodiments of the present disclosure.

In S516, a first portion and a second portion of the metal oxide pattern are formed by conducting a conductor transformation treatment on the second region and the third region on the side, distal from the base substrate, of the metal oxide structure.

In the embodiments of the present disclosure, detailed description of S516 is referred to the description of S315, and thus is not repeated herein in the embodiments of the present disclosure.

In S517, a channel portion of the metal oxide pattern is acquired by removing the photoresist.

In the embodiments of the present disclosure, detailed description of S517 is referred to the description of S316, and thus is not repeated herein in the embodiments of the present disclosure.

In S518, a second insulation layer is formed on the side, distal from the base substrate, of the metal oxide structure.

In the embodiments of the present disclosure, as the formed first insulation layer includes the planarization layer 1052 disposed between the metal oxide pattern 1021 and the color filter layer 103, the planarization of the array substrate 101 is great. The second insulation layer 106 is a third passivation layer disposed on a side, distal from the base substrate 101, of the metal oxide pattern 1021.

In some embodiments, the second insulation layer 106 includes the third passivation layer disposed on a side, distal from the base substrate 101, of the metal oxide pattern 1021, and another planarization layer disposed on a side, distal from the base substrate 101, of the third passivation layer. That is, the array substrate 10 in the technical solutions includes two planarization layers.

In S519, a common electrode is formed on a side, distal from the base substrate, of the second insulation layer.

In the embodiments of the present disclosure, detailed description of S519 is referred to the description of S318, and thus is not repeated herein in the embodiments of the present disclosure.

It should be noted that the sequence of the steps in the method for manufacturing the array substrate in the embodiments of the present disclosure may be adjusted appropriately, and the steps may be added or deleted as required. For example, S502 to S509, S511, and S517 to S518 may be deleted as required, S511 may be performed before S510. Any method change made within the technical scope disclosed in the present disclosure by the person skilled in the art should be included within the scope of protection of the present disclosure, and thus is not described in detail herein.

In summary, a method for manufacturing an array substrate is provided in the embodiments of the present disclosure. The manufactured array substrate includes a color filter layer, such that a distance between a light source on a side, distal from the color filter layer, of the base substrate and the color filter layer is less. Thus, light from the region of the color resist blocks is avoided being emitted from adjacent color resist blocks, and the cross color of the display panel is further avoided, such that the display effect of the display panel is great. In addition, the color resist block is at least partially overlapped with a second portion of the metal oxide pattern in the oxide thin film transistor, such that the overall footprint of the oxide thin film transistor and the color filter layer can be reduced, so as to acquire the display panel of high PPI.

FIG. 35 is a schematic structural diagram of a display panel according to some embodiments of the present disclosure. Referring to FIG. 35, the display panel 001 includes: a cover plate 60, a liquid crystal layer 70, and the array substrate 10 according to above embodiments. For example, the array substrate 10 in the display panel 001 is any array substrate shown in FIG. 5 to FIG. 7. The liquid crystal layer 70 is disposed between the cover plate 60 and the array substrate 10.

For the array substrate shown in FIG. 5 and FIG. 6, a second portion 10213 of a metal oxide structure 1021 and a common electrode 107 in the array substrate 10 drive liquid crystals in the liquid crystal layer 70 to be deflected.

For the array substrate shown in FIG. 7, the pixel electrode 109 and the common electrode 107 in the array substrate 10 drive the liquid crystals in the liquid crystal layer 70 to be deflected.

In the case that the planarization of the array substrate in the display panel is poor (for example, the planarization layer includes a deeper via hole), the liquid crystal arrangement and electric field in the regions of the array substrate 10 are abnormal, and the display of the corresponding region of the display panel is further abnormal. As such, it is necessary to dispose a large-sized black matrix on a side of the cover plate to ensure the display effect of the display panel. An orthogonal projection of the black matrix on the array substrate covers the region with poor planarization (for example, the via hole of the planarization layer). In some embodiments, the aperture ratio of the pixels is less in this solution.

In the embodiments of the present disclosure, referring to FIG. 5 and FIG. 7, the planarization of the array substrate 10 is great. Thus, the planarization of the liquid crystal layer 70 on the side of the array substrate 10 is ensured, the liquid crystal arrangement and electric field in the regions of the array substrate 10 are consistent, and it is not necessary to dispose the large-sized black matrix to ensure the display effect of the display panel on the premise of avoiding the reduce of the aperture ratio of the pixels.

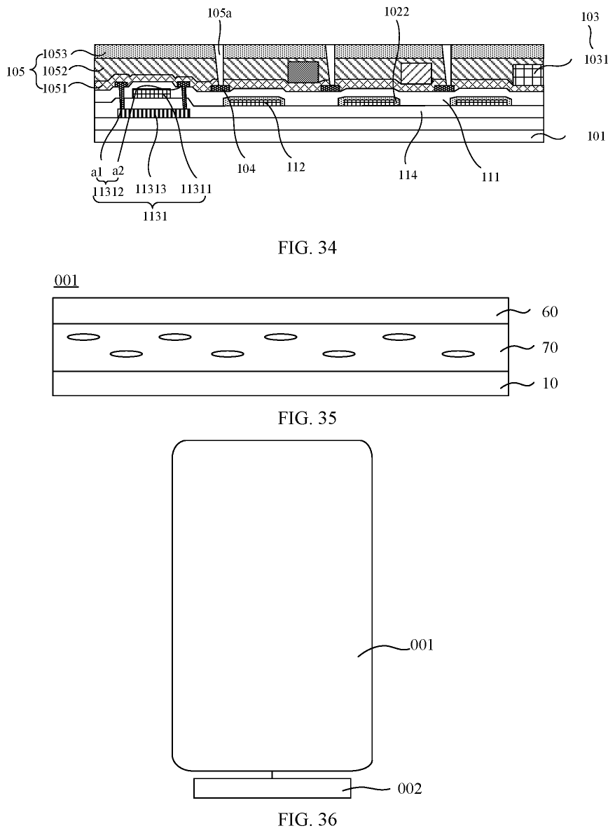

FIG. 36 is a schematic structural diagram of a display device according to some embodiments of the present disclosure. Referring to FIG. 36, the display device includes a power supply assembly 002 and the display panel 001 in above embodiments. The power supply assembly 002 is configured to supply power to the display panel 001.

In some embodiments, the display device is a virtual reality (VR) device or an augmented reality (AR) device. In some embodiments, the display device is also any product or component with a display function and a fingerprint recognition function, such as electronic paper, a mobile phone, a tablet computer, a television, a display, a notebook computer, a digital photo frame, a navigator or the like.

Described above are example embodiments of the present disclosure, and are not intended to limit the present disclosure. Any modifications, equivalent replacements, improvements and the like made within the spirit and principles of the present disclosure should be included within the scope of protection of the present disclosure.

1. An array substrate, comprising:
a base substrate, wherein the base substrate comprises a display region;
a plurality of oxide thin film transistors spaced apart from each other in the display region, wherein each of the plurality of oxide thin film transistors comprises a metal oxide pattern comprising a first portion, a channel portion, and a second portion that are sequentially connected, wherein the first portion is configured to receive a data signal; and
a color filter layer disposed in the display region, wherein the color filter layer is disposed between the metal oxide pattern and the base substrate, and the color filter layer comprises a plurality of color resist blocks of different colors in one-to-one correspondence to the plurality of oxide thin film transistors, wherein an orthogonal projection of each of the plurality of color resist blocks on the base substrate is at least partially overlapped with an orthogonal projection of the second portion of the corresponding oxide thin film transistor on the base substrate.

2. The array substrate according to claim 1, wherein both a conductivity of the first portion and a conductivity of the second portion are greater than a conductivity of the channel portion.

3. The array substrate according to claim 1, further comprising: a plurality of data lines and a first insulation layer;
wherein the plurality of data lines are disposed between the metal oxide pattern and the base substrate, the first insulation layer is disposed between the plurality of data lines and the metal oxide pattern, and the first insulation layer is provided with a plurality of first via holes;
wherein each of the plurality of data lines is electrically connected to the first portion of at least one of the plurality of oxide thin film transistors via at least one of the plurality of first via holes.

4. The array substrate according to claim 3, wherein the first insulation layer is a first passivation layer disposed between the plurality of data lines and the color filter layer;
wherein a distance between a face, proximal to the base substrate, of a target portion of the second portion and the base substrate is greater than a distance between a face, proximal to the base substrate, of the first portion and the base substrate, and greater than a distance between a face, proximal to the base substrate, of the channel portion and the base substrate, wherein the target portion is a section of the second portion with the orthogonal projection on the base substrate overlapped with the orthogonal projection of the color resist block on the base substrate.

5. The array substrate according to claim 3, wherein the first insulation layer comprises: a first passivation layer disposed between the plurality of data lines and the color filter layer, a planarization layer disposed between the color filter layer and the metal oxide pattern, and a second passivation layer disposed between the planarization layer and the metal oxide pattern.

6. The array substrate according to claim 1, further comprising: a second insulation layer disposed on a side, distal from the base substrate, of the second portion, and a common electrode disposed on a side, distal from the base substrate, of the second insulation layer;
wherein an orthogonal projection of the common electrode on the base substrate is at least partially overlapped with the orthogonal projection of the second portion on the base substrate, and the second portion is taken as a pixel electrode to drive, with the common electrode, liquid crystals to be deflected.

7. The array substrate according to claim 1, further comprising: a third insulation layer, a pixel electrode, a fourth insulation layer, and a common electrode that are disposed on a side, distal from the base substrate, of the metal oxide pattern and are sequentially laminated in a direction away from the base substrate; wherein
an orthogonal projection of the pixel electrode on the base substrate is at least partially overlapped with an orthogonal projection of the common electrode on the base substrate;
the third insulation layer is provided with a plurality of second via holes, wherein each of the plurality of second via holes is configured to expose at least part of the second portion of one oxide thin film transistor; and
the pixel electrode is electrically connected to the second portion via the plurality of second via holes.

8. The array substrate according to claim 1, wherein each of the plurality of oxide thin film transistors further comprises: a first gate electrode pattern disposed in the display region; and the array substrate further comprises: a fifth insulation layer;
wherein the first gate electrode pattern is disposed between the metal oxide pattern and the base substrate, the fifth insulation layer is disposed between the first gate electrode pattern and the metal oxide pattern, and in each of the plurality of oxide thin film transistors, an orthogonal projection of the first gate electrode pattern on the base substrate covers an orthogonal projection of the channel portion in the metal oxide pattern on the base substrate.

9. The array substrate according to claim 8, further comprising: a plurality of scan lines extending in a pixel row direction;
wherein the plurality of scan lines are disposed on a side, proximal to the base substrate, of the first gate electrode pattern, each of the plurality of scan lines is at least partially in contact with the first gate electrode pattern of at least one oxide thin film transistor, and a length, in a pixel column direction, of the orthogonal projection of the first gate electrode pattern on the base substrate is greater than a length, in the pixel column direction, of an orthogonal projection of the scan line on the base substrate.

10. The array substrate according to claim 9, wherein the base substrate further comprises a peripheral region on a side of the display region; and the array substrate further comprises: a drive circuit disposed in the peripheral region;
wherein the drive circuit comprises at least one poly-silicon thin film transistor, wherein each poly-silicon thin film transistor comprises: a second gate electrode pattern, and a source-drain electrode pattern;
wherein the second gate electrode pattern and the plurality of scan lines are disposed on a same layer, and the source-drain electrode pattern and a plurality of data lines of the array substrate are disposed on a same layer.

11. The array substrate according to claim 10, wherein each poly-silicon thin film transistor further comprises: an active pattern; and the array substrate further comprises: a sixth insulation layer;
wherein the active pattern is disposed between the second gate electrode pattern and the base substrate, the sixth insulation layer is disposed between the active pattern and the second gate electrode pattern, and the source-drain electrode pattern is electrically connected to the active pattern.

12. A method for manufacturing an array substrate, comprising:
providing a base substrate, wherein the base substrate comprises a display region; and
forming a plurality of oxide thin film transistors spaced apart from each other and a color filter layer in the display region;
wherein each of the plurality of oxide thin film transistors comprises a metal oxide pattern comprising a first portion, a channel portion, and a second portion that are sequentially connected, wherein the first portion is configured to receive a data signal; and the color filter layer is disposed between the metal oxide pattern and the base substrate, and the color filter layer comprises a plurality of color resist blocks of different colors in one-to-one correspondence to the plurality of oxide thin film transistors, wherein an orthogonal projection of each of the plurality of color resist blocks on the base substrate is at least partially overlapped with an orthogonal projection of the second portion of the corresponding oxide thin film transistor on the base substrate.

13. The manufacturing method according to claim 12, wherein forming the metal oxide pattern of the oxide thin film transistor comprises:
forming a metal oxide thin film on a side of the base substrate;
acquiring a metal oxide structure by patterning the metal oxide thin film;
coating a photoresist on a first region on a side, distal from the base substrate, of the metal oxide structure, wherein the side, distal from the base substrate, of the metal oxide structure further comprises a second region and a third region, wherein the second region and the third region are disposed on two sides of the first region;
acquiring the first portion and the second portion of the metal oxide pattern by conducting a conductor transformation treatment on the second region and the third region on the side, distal from the base substrate, of the metal oxide structure; and
acquiring the channel portion of the metal oxide pattern by removing the photoresist.

14. A display panel, comprising: a cover plate, a liquid crystal layer, and an array substrate;
wherein the array substrate comprises:
a base substrate, wherein the base substrate comprises a display region;
a plurality of oxide thin film transistors spaced apart from each other in the display region, wherein each of the plurality of oxide thin film transistors comprises a metal oxide pattern comprising a first portion, a channel portion, and a second portion that are sequentially connected, wherein the first portion is configured to receive a data signal; and
a color filter layer disposed in the display region, wherein the color filter layer is disposed between the metal oxide pattern and the base substrate, and the color filter layer comprises a plurality of color resist blocks of different colors in one-to-one correspondence to the plurality of oxide thin film transistors, wherein an orthogonal projection of each of the plurality of color resist blocks on the base substrate is at least partially overlapped with an orthogonal projection of the second portion of the corresponding oxide thin film transistor on the base substrate;
and the liquid crystal layer is disposed between the cover plate and the array substrate.

15. A display device, comprising: a power supply assembly and the display panel as defined in claim 14;
wherein the power supply assembly is configured to supply power to the display panel.

16. The display panel according to claim 14, wherein both a conductivity of the first portion and a conductivity of the second portion are greater than a conductivity of the channel portion.

17. The display panel according to claim 14, wherein the array substrate further comprises: a plurality of data lines and a first insulation layer;
wherein the plurality of data lines are disposed between the metal oxide pattern and the base substrate, the first insulation layer is disposed between the plurality of data lines and the metal oxide pattern, and the first insulation layer is provided with a plurality of first via holes;
wherein each of the plurality of data lines is electrically connected to the first portion of at least one of the plurality of oxide thin film transistors via at least one of the plurality of first via holes.

18. The display panel according to claim 17, wherein the first insulation layer is a first passivation layer disposed between the plurality of data lines and the color filter layer;
wherein a distance between a face, proximal to the base substrate, of a target portion of the second portion and the base substrate is greater than a distance between a face, proximal to the base substrate, of the first portion and the base substrate, and greater than a distance between a face, proximal to the base substrate, of the channel portion and the base substrate, wherein the target portion is a section of the second portion with the orthogonal projection on the base substrate overlapped with the orthogonal projection of the color resist block on the base substrate.

19. The display panel according to claim 17, wherein the first insulation layer comprises: a first passivation layer disposed between the plurality of data lines and the color filter layer, a planarization layer disposed between the color filter layer and the metal oxide pattern, and a second passivation layer disposed between the planarization layer and the metal oxide pattern.

20. The display panel according to claim 14, wherein the array substrate further comprises: a second insulation layer disposed on a side, distal from the base substrate, of the second portion, and a common electrode disposed on a side, distal from the base substrate, of the second insulation layer;
wherein an orthogonal projection of the common electrode on the base substrate is at least partially overlapped with the orthogonal projection of the second portion on the base substrate, and the second portion is taken as a pixel electrode to drive, with the common electrode, liquid crystals to be deflected.
